(19) United States
(12) Patent Application Publication
(10) Pub. No.: US 2026/0013109 A1
(43) Pub. Date: Jan. 8, 2026

(54) SEMICONDUCTOR DEVICE

(71) Applicant: SAMSUNG ELECTRONICS CO., LTD., Suwon-si (KR)

(72) Inventors: DAEWON HA, Suwon-si (KR); Chang hyuck SUNG, Suwon-si (KR)

(73) Assignee: SAMSUNG ELECTRONICS CO., LTD., Suwon-si (KR)

(21) Appl. No.: 19/028,661

(22) Filed: Jan. 17, 2025

(30) Foreign Application Priority Data
Jul. 8, 2024 (KR) 10-2024-0089865

(51) Int. Cl. H10B 12/00

(52) U.S. Cl. CPC H10B 12/33; H10B 12/05

(57) ABSTRACT

A semiconductor device includes: a first data storage pattern and a second data storage pattern; a first storage contact on the first data storage pattern and a second storage contact on the second data storage pattern; a first channel pattern on the first storage contact and a second channel pattern on the second storage contact; a first word line and a second word line located between the first channel pattern and the second channel pattern, the first word line provided on the first channel pattern side and the second word line provided on the second channel pattern side; a bit line located on the first channel pattern and the second channel pattern, extending along the first direction; and a first interlayer between the first storage contact and the first channel pattern and between the second storage contact and the second channel pattern.

### CROSS-REFERENCE TO RELATED APPLICATION

This application is based on and claims priority under 35 U.S.C. § 119 to Korean Patent Application No. 10-2024-0089865, filed on Jul. 8, 2024, in the Korean Intellectual Property Office, the disclosure of which is incorporated by reference herein in its entirety.

### BACKGROUND

### 1. Field

The disclosure relates to a semiconductor device.

### 2. Description of Related Art

Semiconductors belong to an intermediate region between a conductor and an insulator, and refer to a material that conducts electricity under certain conditions. Various semiconductor devices (for example, memory devices) may be manufactured using these semiconductor materials. Such semiconductor devices may be used in various electronic devices.

As electronic devices become more miniaturized and highly integrated, there is a need to finely form the patterns that constitutes semiconductor device. As the width of these micro-patterns gradually decreases, process difficulty increases and the defect rate of semiconductor devices also increases.

### SUMMARY

Provided is a semiconductor device capable of improving a contact area between a channel pattern and a storage contact or a contact area between a channel pattern and a bit line in a vertical channel transistor (VCT) structure, reducing contact resistance to maximize on-current (Iₒₙ) enhancement, and securing an effective separation distance from a field perspective between a horizontal portion of a channel pattern and a word line or between a channel pattern and a bit line.

According to an aspect of the disclosure, a semiconductor device includes: a first data storage pattern and a second data storage pattern spaced apart along a first direction; a first storage contact on the first data storage pattern and a second storage contact on the second data storage pattern; a first channel pattern on the first storage contact and a second channel pattern on the second storage contact; a first word line and a second word line extending along a second direction different from the first direction and located between the first channel pattern and the second channel pattern, the first word line provided on the first channel pattern side and the second word line provided on the second channel pattern side; a bit line located on the first channel pattern and the second channel pattern, the bit line extending along the first direction; and a first interlayer between the first storage contact and the first channel pattern and between the second storage contact and the second channel pattern.

According to an aspect of the disclosure, a semiconductor device includes: a first data storage pattern and a second data storage pattern spaced apart from each other along a first direction; a first storage contact on the first data storage pattern and a second storage contact on the second data storage pattern; a first channel pattern on the first storage contact and a second channel pattern on the second storage contact; a first word line and a second word line extending along a second direction different from the first direction and located between the first channel pattern and the second channel pattern, the first word line provided on the first channel pattern side and the second word line provided on the second channel pattern side; a bit line located on the first channel pattern and the second channel pattern and extending along the first direction; and a second interlayer between the bit line and the first channel pattern and between the bit line and the second channel pattern.

According to an aspect of the disclosure, a semiconductor device includes: a first data storage pattern and a second data storage pattern spaced apart along a first direction; a first storage contact on the first data storage pattern and a second storage contact on the second data storage pattern; a first channel pattern on the first storage contact and a second channel pattern on the second storage contact; a first word line and a second word line extending along a second direction different from the first direction and provided between the first channel pattern and the second channel pattern, the first word line provided on the first channel pattern side and the second word line provided on the second channel pattern side; and a bit line located on the first channel pattern and the second channel pattern and extending along the first direction, wherein the first channel pattern includes: a first vertical portion extending in a third direction perpendicular to the first direction and the second direction, and a first horizontal portion extending from a lower end of the first vertical portion in the first direction and covering an upper surface of the first storage contact, wherein the second channel pattern includes: a second vertical portion extending in a third direction perpendicular to the first direction and the second direction, and a second horizontal portion extending from a lower end of the second vertical portion in the first direction and covering an upper surface of the second storage contact, wherein the first horizontal portion of the first channel pattern extends in the first direction from the lower end of the first vertical portion, and extends in a direction away from the first word line, and wherein the second horizontal portion of the second channel pattern extends from the lower end of the second vertical portion in the first direction, and extends in a direction away from the second word line.

According to embodiments, a semiconductor device can improve a contact area between a channel pattern and a storage contact or a contact area between a channel pattern and a bit line in a vertical channel transistor (VCT) structure, reduce contact resistance, maximize on-current (Iₒₙ) enhancement, and secure an effective separation distance from a field perspective between a horizontal portion of a channel pattern and a word line or between a channel pattern and a bit line.

### BRIEF DESCRIPTION OF DRAWINGS

The above and other aspects, features, and advantages of certain embodiments of the disclosure will be more apparent from the following description taken in conjunction with the accompanying drawings, in which:

FIG. 1 is a plan view illustrating a semiconductor device according to an embodiment;

FIG. 2 is a cross-sectional view taken along line A-A′ of FIG. 1;

FIG. 3 is a cross-sectional view taken along line B-B′ of FIG. 1;

FIGS. 4 and 5 are cross-sectional views showing semiconductor devices according to embodiments, corresponding to FIGS. 2 and 3, respectively;

FIGS. 6 and 7 are cross-sectional views showing semiconductor devices according to embodiments, corresponding to FIGS. 2 and 3, respectively;

FIGS. 8 to 39 are cross-sectional views showing a method for manufacturing a semiconductor device according to an embodiment of the disclosure in the order of processes; and

FIGS. 40 to 45 are cross-sectional views showing a method of manufacturing a semiconductor device according to a process sequence according to embodiments;

### DETAILED DESCRIPTION

The disclosure will be described more fully hereinafter with reference to the accompanying drawings, in which embodiments of the disclosure are shown. As those skilled in the art would realize, the described embodiments may be modified in various different ways, all without departing from the spirit or scope of the disclosure.

The description merely illustrates the principles of the disclosure. Those skilled in the art will be able to devise one or more arrangements that, although not explicitly described herein, embody the principles of the disclosure. Furthermore, all examples recited herein are principally intended expressly to be only for explanatory purposes to help the reader in understanding the principles of the disclosure and the concepts contributed by the inventor to furthering the art and are to be construed as being without limitation to such specifically recited examples and conditions. Moreover, all statements herein reciting principles, aspects, and embodiments of the disclosure, as well as specific examples thereof, are intended to encompass equivalents thereof.

Terms used in the disclosure are used only to describe a specific embodiment, and may not be intended to limit the scope of another embodiment. A singular expression may include a plural expression unless it is clearly meant differently in the context. The terms used herein, including a technical or scientific term, may have the same meaning as generally understood by a person having ordinary knowledge in the technical field described in the present disclosure. Terms defined in a general dictionary among the terms used in the present disclosure may be interpreted with the same or similar meaning as a contextual meaning of related technology, and unless clearly defined in the present disclosure, it is not interpreted in an ideal or excessively formal meaning. In some cases, even terms defined in the disclosure cannot be interpreted to exclude embodiments of the present disclosure.

The size and thickness of each constituent element as shown in the drawings are randomly indicated for better understanding and ease of description, and this disclosure is not necessarily limited to as shown. In the drawings, the thickness of layers, regions, etc., are exaggerated for clarity. In the drawings, for better understanding and ease of description, the thickness of some layers and areas is exaggerated.

When an element such as a layer, film, region, or substrate is referred to as being “on” another element, it can be directly on the other element or intervening elements may also be present. In contrast, when an element is referred to as being “directly on” another element, there are no intervening elements present. The word “on” or “above” means being disposed on or below the object portion, and does not necessarily mean being disposed on the upper side of the object portion based on a gravitational direction.

Unless explicitly described to the contrary, the word “comprise,” and variations such as “comprises” or “comprising,” imply the inclusion of stated elements but not the exclusion of any other elements.

In the disclosure, the phrase “on a plane” means viewing a target portion from the top, and the phrase “on a cross-section” means viewing a cross-section formed by vertically cutting a target portion from the side.

In the disclosure, in order to determine whether a specific condition is satisfied or fulfilled, an expression of more than or less than may be used, but this is only a description for expressing an example, and does not exclude description of more than or equal to or less than or equal to. A condition described as ‘more than or equal to’ may be replaced with ‘more than’, a condition described as ‘less than or equal to’ may be replaced with ‘less than’, and a condition described as ‘more than or equal to and less than’ may be replaced with ‘more than and less than or equal to’.

Throughout the disclosure, two directions parallel to and intersecting the upper surface of the substrate are defined as the first direction DR1 and the second direction DR2, respectively, and the direction perpendicular to the upper surface of the substrate is described as the third direction DR3. For example, the first direction DR1 and the second direction DR2 may be perpendicular to each other.

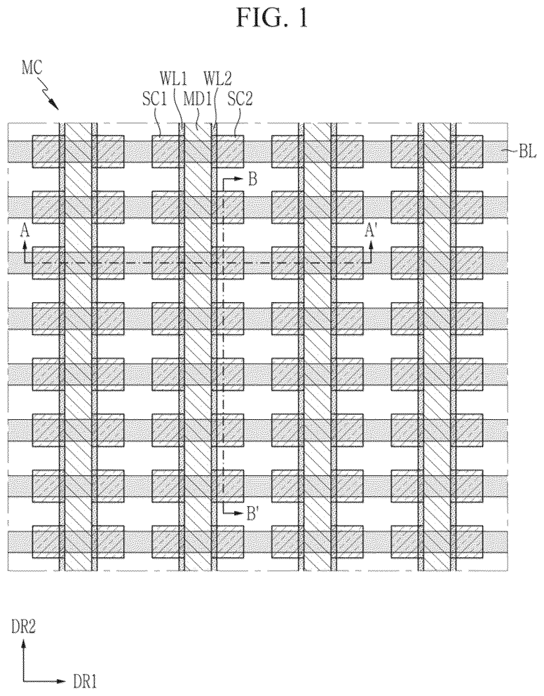

Hereinafter, a semiconductor device according to an embodiment will be described with reference to FIGS. 1 to 3.

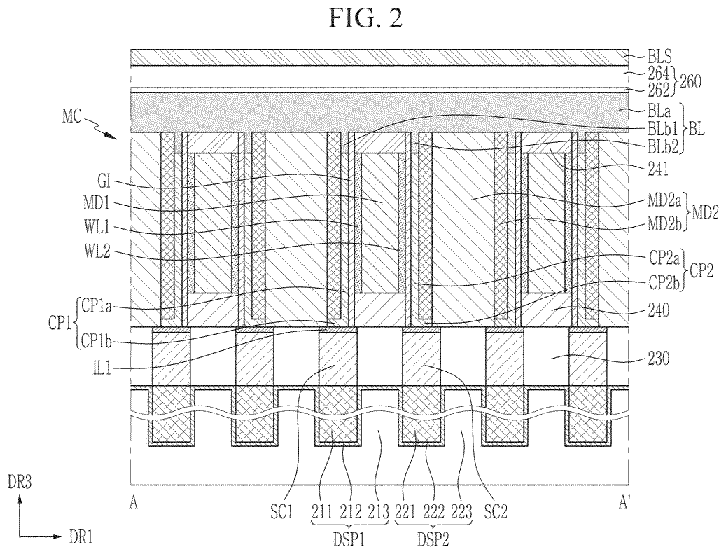

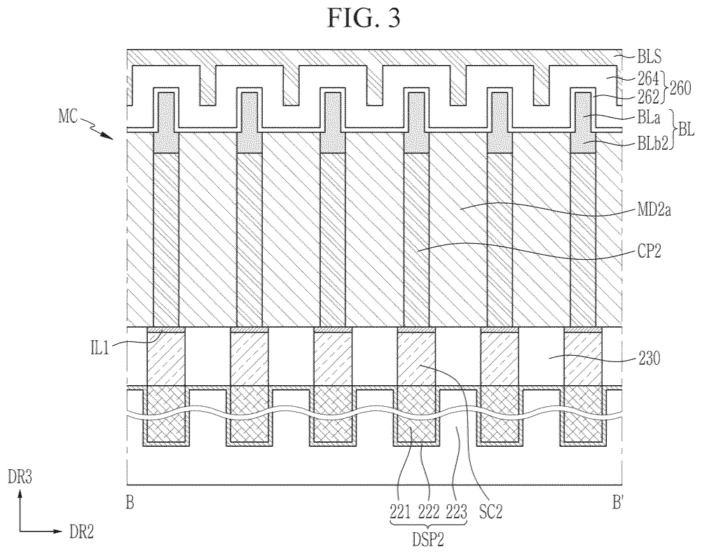

FIG. 1 is a plan view showing a semiconductor device according to an embodiment, FIG. 2 is a cross-sectional view taken along line A-A′ of FIG. 1, and FIG. 3 is a cross-sectional view taken along line B-B′ of FIG. 1.

FIG. 1 illustrates a first storage contact SC1, a second storage contact SC2, a first word line WL1, a second word line WL2, a first insulating pattern MD1, and a bit line BL included in a memory cell MC.

Referring to FIGS. 1 to 3, the semiconductor device may include a memory cell MC. The memory cell MC may include or correspond to a memory cell of a volatile memory device, or a memory cell of a non-volatile memory device. For example, a memory cell MC can be configured as a dynamic random access memory (DRAM). In a memory cell MC, multiple unit memory cells for storing information may be arranged in a regular, repeated manner. A unit memory cell may include at least one transistor and at least one capacitor.

In an embodiment, the semiconductor device may further include a driving circuit that generates a signal for driving a memory cell MC and wiring that transmits such a signal. For example, a semiconductor device may include a core region and a peripheral region, and a sense amplifier or a sub word line driver may be located in the core region. The peripheral region may house a row decoder or a column decoder.

For example, a memory cell MC may be connected to a core region and a peripheral region. The memory cell MC and the core region and the peripheral region may be bonded through a bonding insulating layer. The core region and the peripheral region may be bonded to the upper or lower portions of the memory cell MC. At this time, the circuits and wirings located in the core region and the peripheral region and the memory cell MC may be connected by a contact member penetrating the memory cell MC.

However, embodiments of the disclosure are not limited to the above embodiment, and the positional relationship between the core region, the peripheral region, and the memory cell MC may be changed in various ways. In an embodiment, the circuits and wirings located in the core region and the peripheral region and the memory cells (MC) may be connected by hybrid bonding.

A memory cell MC includes a first data storage pattern DSP1 and a second data storage pattern DSP2, a first storage contact SC1 and a second storage contact SC2 located respectively on the first data storage pattern DSP1 and the second data storage pattern DSP2, a first channel pattern CP1 and a second channel pattern CP2 located respectively on the first storage contact SC1 and the second storage contact SC2, a first word line WL1 and a second word line WL2 between the first channel pattern CP1 and the second channel pattern CP2, and a bit line BL on the first channel pattern CP1 and the second channel pattern CP2.

Each of the first data storage pattern DSP1 and the second data storage pattern DSP2 may be, for example, a capacitor. The first data storage pattern DSP1 and the second data storage pattern DSP2 may each include first capacitor electrodes 211 and 221, second capacitor electrodes 213 and 223, and dielectric layers 212 and 222 between the first capacitor electrodes 211 and 221 and the second capacitor electrodes 213 and 223.

The first capacitor electrodes 211 and 221 may be in contact with the first storage contact SC1 and the second storage contact SC2. For example, the first capacitor electrodes 211 and 221 may be electrically connected to the first storage contact SC1 and the second storage contact SC2. The first capacitor electrode 211 of the first data storage pattern DSP1 may be connected to the first storage contact SC1, and the first capacitor electrode 221 of the second data storage pattern DSP2 may be connected to the second storage contact SC2. A first data storage pattern DSP1 may be connected to a first channel pattern CP1 via a first storage contact SC1, and a second data storage pattern DSP2 may be connected to a second channel pattern CP2 via a second storage contact SC2.

For example, a semiconductor device may include a plurality of first data storage patterns DSP1 and a plurality of second data storage patterns DSP2. The first capacitor electrodes 211 and 221 of the plurality of first data storage patterns DSP1 and the plurality of second data storage patterns DSP2 are separated from each other. The same voltage may be applied to the second capacitor electrodes 213 and 223 of the plurality of first data storage patterns DSP1 and the plurality of second data storage patterns DSP2, and may be formed integrally. The dielectric layers 212 and 222 of the plurality of first data storage patterns DSP1 and the plurality of second data storage patterns DSP2 may be formed integrally.

However, embodiments of the disclosure are not limited to the above embodiment, and the first data storage pattern DSP1 and the second data storage pattern DSP2 may be variable resistance patterns that may be switched into two resistance states by an electrical pulse applied to the memory element. For example, the first data storage pattern DSP1 and the second data storage pattern DSP2 may include a phase-change material, a perovskite compound, a transition metal oxide, a magnetic material, a ferromagnetic material, or an antiferromagnetic material whose crystal state changes depending on the amount of current.

The first data storage pattern DSP1 and the second data storage pattern DSP2 may be spaced apart from each other along the first direction DR1. When the first data storage pattern DSP1 and the second data storage pattern DSP2 are formed of capacitors, this means that the first capacitor electrodes 211 and 221 are spaced apart from each other, and the dielectric layers 212 and 222 and the second capacitor electrodes 213 and 223 may be connected to each other.

The first storage contact SC1 and the second storage contact SC2 may be located on the first data storage pattern DSP1 and the second data storage pattern DSP2, respectively. The first storage contact SC1 may be located on the first capacitor electrode 211 of the first data storage pattern DSP1 and, for example, may be electrically connected to the first capacitor electrode 211 of the first data storage pattern DSP1. The lower surface of the first storage contact SC1 may be in contact with the upper surface of the first capacitor electrode 211 of the first data storage pattern DSP1. The first storage contact SC1 may have a similar width in the first direction DR1 as the first capacitor electrode 211 of the first data storage pattern DSP1. The first storage contact SC1 may overlap the first capacitor electrode 211 of the first data storage pattern DSP1 in the third direction DR3.

The second storage contact SC2 may be, for example, located on the first capacitor electrode 221 of the second data storage pattern DSP2 and may be electrically connected to the first capacitor electrode 221 of the second data storage pattern DSP2. The lower surface of the second storage contact SC2 may be in contact with the upper surface of the first capacitor electrode 221 of the second data storage pattern DSP2. The second storage contact SC2 may have a similar width in the first direction DR1 as the first capacitor electrode 221 of the second data storage pattern DSP2. The second storage contact SC2 may overlap the first capacitor electrode 221 of the second data storage pattern DSP2 in the third direction DR3.

The first storage contact SC1 may have a layout substantially identical to that of the first capacitor electrode 211 of the first data storage pattern DSP1. The second storage contact SC2 may have substantially the same arrangement as the first capacitor electrode 221 of the second data storage pattern DSP2. The first storage contact SC1 and the second storage contact SC2 may be spaced apart from each other along the first direction DR1. The separation distance between the first storage contact SC1 and the second storage contact SC2 may be similar to the separation distance between the first capacitor electrode 211 of the first data storage pattern DSP1 and the first capacitor electrode 221 of the second data storage pattern DSP2. The number of the first storage contacts SC1 and the second storage contacts SC2 may correspond to the number of the first capacitor electrodes 211 of the first data storage pattern DSP1 and the number of the first capacitor electrodes 221 of the second data storage pattern DSP2, respectively. The number of first storage contacts SC1 may be substantially equal to the number of first capacitor electrodes 211 of the first data storage pattern DSP1. The number of second storage contacts SC2 may be substantially equal to the number of first capacitor electrodes 221 of the second data storage pattern DSP2.

The semiconductor device may include a plurality of first storage contacts SC1 and a plurality of second storage contacts SC2. The first storage contact SC1 and the second storage contact SC2 may be alternately and repeatedly located along the first direction DR1. A plurality of first storage contacts SC1 may be spaced apart along the second direction DR2. A plurality of second storage contacts SC2 may be spaced apart along the second direction DR2. In other words, a column of a plurality of first storage contacts SC1 and a column of a plurality of second storage contacts SC2 may be alternately and repeatedly located.

The first storage contact SC1 and the second storage contact SC2 may include doped polysilicon, a metal, a conductive metal nitride, a conductive metal oxide, or a combination thereof. For example, the first storage contact SC1 and the second storage contact SC2 may include, but are not limited to, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx (0<x≤2), RuOₓ (0<x≤2), or a combination thereof.

The semiconductor device may further include a second interlayer insulating layer 230 located on the first data storage pattern DSP1 and the second data storage pattern DSP2. A second interlayer insulating layer 230 may be located between the first storage contact SC1 and the second storage contact SC2. The second interlayer insulating layer 230 may be located between a plurality of first storage contacts SC1 and may be located between a plurality of second storage contacts SC2. On a plane, the first storage contact SC1 may be surrounded by a second interlayer insulating layer 230, and the second storage contact SC2 may be surrounded by a second interlayer insulating layer 230.

The second interlayer insulating layer 230 may include an insulating material. For example, the second interlayer insulating layer 230 may include silicon oxide, silicon nitride, or silicon oxynitride.

The semiconductor device may further include a storage capping pattern 240 located on the first storage contact SC1 and the second storage contact SC2. The storage capping pattern 240 may cover a portion of the upper surface of the first storage contact SC1 and the second storage contact SC2, and may not cover the remaining portion. The storage capping pattern 240 may cover the upper surface of the second interlayer insulating layer 230 between the first storage contact SC1 and the second storage contact SC2. In other words, the storage capping pattern 240 can sequentially cover a portion of the first storage contact SC1, a portion of the second interlayer insulating layer 230, and a portion of the second storage contact SC2.

A row of a plurality of first storage contacts SC1 and a row of a plurality of second storage contacts SC2 may form a pair of storage contact rows. The storage capping pattern 240 may overlap a pair of storage contact columns in a third direction DR3 and may extend along a second direction DR2. The storage capping pattern 240 may not cover the space between one pair of storage contact columns and another adjacent pair of storage contact columns. A plurality of storage capping patterns 240 may be spaced apart along the first direction DR1.

The storage capping pattern 240 may include an insulating material. For example, the storage capping pattern 240 may include silicon oxide, silicon nitride, or silicon oxynitride. The storage capping pattern 240 may include the same material as the second interlayer insulating layer 230. At this time, the interface between the storage capping pattern 240 and the second interlayer insulating layer 230 may not be visible. In other words, the storage capping pattern 240 and the second interlayer insulating layer 230 may be formed integrally.

The first word line WL1 and the second word line WL2 may be located on the storage capping pattern 240. The first word line WL1 and the second word line WL2 may extend along the second direction DR2. The first word line WL1 and the second word line WL2 may be spaced apart in the first direction DR1. The first word line WL1 may overlap the first storage contact SC1 in the third direction DR3. A first word line WL1 may overlap a row of first storage contacts SC1 spaced apart along a second direction DR2. The second word line WL2 may overlap the second storage contact SC2 in the third direction DR3. The second word line WL2 may overlap a row of second storage contacts SC2 spaced apart along the second direction DR2. The number of the first word line WL1 and the second word line WL2 may correspond to the number of the first storage contact SC1 column and the second storage contact SC2 column, respectively. The number of first word lines WL1 may be substantially equal to the number of first storage contact SC1 rows. The number of second word lines WL2 may be substantially equal to the number of rows of second storage contacts SC2.

The width of the first word line WL1 along the first direction DR1 may be smaller than the width of the first storage contact SC1 along the first direction DR1. The width of the first word line WL1 along the first direction DR1 may be smaller than the length along the third direction DR3. The width of the second word line WL2 along the first direction DR1 may be smaller than the width of the second storage contact SC2 along the first direction DR1. The width of the second word line WL2 along the first direction DR1 may be smaller than the length along the third direction DR3.

The first word line WL1 and the second word line WL2 may include doped polysilicon, a metal, a conductive metal nitride, a conductive metal oxide, or a combination thereof. For example, the first word line WL1 and the second word line WL2 may include, but are not limited to, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx (0<x≤2), RuOₓ (0<x≤2), or a combination thereof.

The semiconductor device may further include a first insulating pattern MD1 between a first word line WL1 and a second word line WL2. A first word line WL1 and a second word line WL2 may be located on both sides of the first direction DR1 of the first insulating pattern MD1. For example, a first word line WL1 may be located on the left side of the first insulating pattern MD1, and a second word line WL2 may be located on the right side of the first insulating pattern MD1. The left side of the first insulating pattern MD1 may be in contact with the first word line WL1, and the right side of the first insulating pattern MD1 may be in contact with the second word line WL2. The first insulating pattern MD1 may be located on the storage capping pattern 240.

The width of the first insulating pattern MD1 along the first direction DR1 may be smaller than the length along the third direction DR3. The width of the first insulating pattern MD1 along the first direction DR1 may be greater than the width of the first word line WL1 along the first direction DR1. The width of the first insulating pattern MD1 along the first direction DR1 may be greater than the width of the second word line WL2 along the first direction DR1. The length of the first insulating pattern MD1 along the third direction DR3 may be similar to the length of the first word line WL1 along the third direction DR3. The length of the first insulating pattern MD1 along the third direction DR3 may be similar to the length of the first word line WL1 along the third direction DR3.

The upper surface of the first insulating pattern MD1 may be disposed at substantially the same level as the upper surface of the first word line WL1 and the upper surface of the second word line WL2. The lower surface of the first insulating pattern MD1 may be disposed at substantially the same level as the lower surface of the first word line WL1 and the lower surface of the second word line WL2. The semiconductor device may include a plurality of first insulating patterns MD1.

A plurality of first insulating patterns MD1 may be spaced apart from each other along the first direction. The first insulating pattern MD1 may be located between the first word line WL1 and the second word line WL2 constituting one word line pair, and may not be located between adjacent word line pairs. The number of first insulating patterns MD1 can correspond to the number of word line pairs. The number of first insulating patterns MD1 may be substantially equal to the number of word line pairs. The number of first insulating patterns MD1 may be substantially equal to the number of first word lines WL1. The number of first insulating patterns MD1 may be substantially equal to the number of second word lines WL2. The number of first insulating patterns MD1 may correspond to the number of storage capping patterns 240.

The first insulating pattern MD1 may include an insulating material. The first insulating pattern MD1 may include a low-k material having a lower dielectric constant than silicon oxide. For example, the low-k material may include flowable oxide (FOX), tonne silazane (TOSZ), undoped silicate glass (USG), borosilicate glass (BSG), phosphosilicate glass (PSG), borophosphosilicate glass (BPSG), plasma enhanced tetra ethyl ortho silicate (PETEOS), fluoride silicate glass (FSG), carbon doped silicon oxide (CDO), xerogel, aerogel, amorphous fluorinated carbon, organo silicate glass (OSG), parylene, bis-benzocyclobutenes (BCB), SILK, polyimide, a porous polymeric material, or a combination thereof. However, embodiments of the disclosure are not limited to the above embodiment, and the first insulating pattern MD1 may include silicon oxide, silicon oxynitride, or silicon nitride.

The semiconductor device may further include a gate capping pattern 241 on the first word line WL1, the second word line WL2, and the first insulating pattern MD1. The gate capping pattern 241 may cover the upper surface of the first word line WL1, the upper surface of the second word line WL2, and the upper surface of the first insulating pattern MD1.

The side of the gate capping pattern 241 may be covered by a gate insulating pattern GI described later. The gate capping pattern 241 may overlap the storage capping pattern 240 in the third direction DR3. A plurality of gate capping patterns 241 may be spaced apart from each other along the first direction DR1.

The gate capping pattern 241 may include an insulating material. For example, the gate capping pattern 241 may include silicon oxide, silicon nitride, or silicon oxynitride.

The semiconductor device may further include a gate insulating pattern GI located between a first word line WL1 and a first channel pattern CP1 described later and between a second word line WL2 and a second channel pattern CP2 described later.

For example, the left side of the first word line WL1 may be covered by a gate insulating pattern GI, and the right side of the first word line WL1 may be covered by a first insulating pattern MD1. The left side of the first word line WL1 may be in contact with the gate insulating pattern GI, and the right side of the first word line WL1 may be in contact with the first insulating pattern MD1. However, embodiments of the disclosure are not limited to the above embodiment, and another layer may be further located between the first word line WL1 and the gate insulating pattern GI and/or between the first word line WL1 and the first insulating pattern MD1.

The right side of the second word line WL2 may be covered by a gate insulating pattern GI, and the left side of the second word line WL2 may be covered by a first insulating pattern MD1. The right side of the second word line WL2 may be in contact with the gate insulating pattern GI, and the left side of the second word line WL2 may be in contact with the first insulating pattern MD1. However, embodiments of the disclosure are not limited to the above embodiment, and another layer may be further located between the second word line WL2 and the gate insulating pattern GI and/or between the second word line WL2 and the first insulating pattern MD1.

The gate insulating pattern GI may be located between the storage capping pattern 240 and the first channel pattern CP1 and between the storage capping pattern 240 and the second channel pattern CP2. For example, the left and right sides of the storage capping pattern 240 may be covered by a gate insulating pattern GI.

The gate insulating pattern GI may be located between the gate capping pattern 241 and the first channel pattern CP1 and between the gate capping pattern 241 and the second channel pattern CP2. For example, the left and right sides of the gate capping pattern 241 may be covered by a gate insulating pattern GI.

In some embodiments, the gate insulating pattern GI may be located on the first word line WL1 and the second word line WL2, or on the gate capping pattern 241. For example, the gate insulating pattern GI may be located continuously to cover one side and an upper surface of the first word line WL1, an upper surface of the gate capping pattern 241, and an upper surface and one side of the second word line WL2.

The gate insulating pattern GI may include silicon oxide, silicon nitride, silicon oxynitride, a high-k material having a higher dielectric constant than silicon oxide, or a combination thereof. For example, the high-k material may include ZrO₂, ZrON, HfO₂, HfON, ZrSiOx, ZrSiON, HfSiOx, HfSiON, HfZrO₂, ZrHfSiOx, La₂O₃, LaAlO, TaO, TiO, BaSrTiO, BaTiO, SrTiO, YO, Al₂O₃, PbScTaO, or a combination thereof.

The first channel pattern CP1 and the second channel pattern CP2 may be located on both sides of the first direction DR1 of the first insulating pattern MD1. For example, the first channel pattern CP1 may be located on the left side of the first insulating pattern MD1, and the second channel pattern CP2 may be located on the right side of the first insulating pattern MD1. The first channel pattern CP1 may be located on the left side of the first word line WL1. A gate insulating pattern GI may be located between the first channel pattern CP1 and the first word line WL1. The first channel pattern CP1 may be spaced apart from the first word line WL1 with a gate insulating pattern GI therebetween. The second channel pattern CP2 may be located on the right side of the second word line WL2. A gate insulating pattern GI may be located between the second channel pattern CP2 and the second word line WL2. The second channel pattern CP2 may be spaced apart from the second word line WL2 with a gate insulating pattern GI therebetween.

The first word line WL1 and the second word line WL2 are located between a first channel pattern CP1 and a second channel pattern CP2, and the first word line WL1 may be located on the first channel pattern CP1 side, and the second word line WL1 may be located on the second channel pattern CP1 side. The first channel pattern CP1 may be adjacent to the first word line WL1, and the second channel pattern CP2 may be adjacent to the second word line WL2. At this time, a first insulating pattern MD1 may be located between the first word line WL1 and the second word line WL2.

The storage capping pattern 240 may be located between the first channel pattern CP1 and the second channel pattern CP2. For example, a first channel pattern CP1 may be located on the left side of the storage capping pattern 240, and a second channel pattern CP2 may be located on the right side of the storage capping pattern 240. The first channel pattern CP1 and the second channel pattern CP2 may be in contact with the side of the storage capping pattern 240. However, embodiments of the disclosure are not limited to the above embodiment, and another layer may be further located between at least one of the first channel pattern CP1 and the second channel pattern CP2 and the storage capping pattern 240.

The first channel pattern CP1 and the second channel pattern CP2 may be connected to the first storage contact SC1 and the second storage contact SC2, respectively. The first channel pattern CP1 may be electrically connected to the first storage contact SC1. The first channel pattern CP1 may be in contact with the upper surface of the first storage contact SC1. The second channel pattern CP2 may be electrically connected to the second storage contact SC2. The second channel pattern CP2 may be in contact with the upper surface of the second storage contact SC2. The number of the first channel pattern CP1 and the second channel pattern CP2 may correspond to the number of the first storage contact SC1 and the second storage contact SC2, respectively. The number of first channel patterns CP1 may be substantially equal to the number of first storage contacts SC1. The number of second channel patterns CP2 may be substantially equal to the number of second storage contacts SC2.

The width of the first channel pattern CP1 along the first direction DR1 may be smaller than the length along the third direction DR3. The length of the first channel pattern CP1 along the third direction DR3 may be smaller than the length of the gate insulating pattern GI along the third direction DR3. The width of the second channel pattern CP2 along the first direction DR1 may be smaller than the length along the third direction DR3. The length of the second channel pattern CP2 along the third direction DR3 may be smaller than the length of the gate insulating pattern GI along the third direction DR3.

The first channel pattern CP1 and the second channel pattern CP2 may include a semiconductor material. The first channel pattern CP1 and the second channel pattern CP2 may include an oxide semiconductor material. The oxide semiconductor material may be in a combination of at least two or more of In, Ga, Zn, Al, Sn, and Hf, but is not limited thereto. The oxide semiconductor material may further include a material such as Si, Mg, Ta, La, Nd, Ce, Sc, Cr, Co, Nb, Mo, Ba, Gd, Ti, W, Pd, Ru, Ni, or Mn in the composition. For example, the first channel pattern CP1 and the second channel pattern CP2 may include indium gallium zinc oxide (IGZO), indium tin zinc oxide (ITZO), indium zinc oxide (IZO), zinc oxide (ZnO), zinc tin oxide (ZTO), zinc oxynitride (ZnON), zirconium zinc tin oxide (ZZTO), tin oxide (SnO), hafnium indium zinc oxide (HIZO), gallium zinc tin oxide (GZTO), aluminum zinc tin oxide (AZTO), ytterbium gallium zinc oxide (YGZO), indium gallium oxide (IGO) or a combination thereof. However, embodiments of the disclosure are not limited to the above embodiment, and the oxide semiconductor material included in the first channel pattern CP1 and the second channel pattern CP2 may be variously changed.

The first channel pattern CP1 may include a first vertical portion CP1a extending along a third direction DR3, and a first horizontal portion CP1b extending in the first direction DR1 from a lower end of the first vertical portion CP1a.

The second channel pattern CP2 may include a second vertical portion CP2a extending along a third direction DR3, and a second horizontal portion CP2b extending in the first direction DR1 from a lower end of the second vertical portion CP2a.

The first vertical portion CP1a of the first channel pattern CP1 may be located on one side of the gate insulating pattern GI, for example, on the left side. The first horizontal portion CP1b of the first channel pattern CP1 may extend in the first direction DR1. The first horizontal portion CP1b of the first channel pattern CP1 may be located on the first storage contact SC1. The first horizontal portion CP1b of the first channel pattern CP1 may cover the upper surface of the first storage contact SC1. The first horizontal portion CP1b of the first channel pattern CP1 may be in contact with the first storage contact SC1 and be electrically connected.

The second vertical portion CP2a of the second channel pattern CP2 may be located on the other side of the gate insulating pattern GI, for example, on the right side. The second horizontal portion CP2b of the second channel pattern CP2 may extend in the first direction DR1. The second horizontal portion CP2b of the second channel pattern CP2 may be located on the second storage contact SC2. The second horizontal portion CP2b of the second channel pattern CP2 may cover the upper surface of the second storage contact SC2. The second horizontal portion CP2b of the second channel pattern CP2 may be in contact with the second storage contact SC2 and be electrically connected.

In a vertical channel transistor (VCT) structure, since the contact area between the first and second channel patterns CP1 and CP2 and the first and second storage contacts SC1 and SC2 decreases exponentially, there is a need to improve the contact resistance. Since the first and second channel patterns CP1 and CP2 have first and second horizontal portions CP1b and CP2b covering the upper surfaces of the first and second storage contacts SC1 and SC2, the contact area between the first and second channel patterns CP1 and CP2 and the first and second storage contacts SC1 and SC2 may be improved.

In an embodiment, by inserting a first interlayer IL1 between the first and second channel patterns CP1 and CP2 and the first and second storage contacts SC1 and SC2, the contact resistance may be reduced and the on-current (Iₒₙ) enhancement may be maximized.

The first interlayer IL1 may be located between the first storage contact SC1 and the first channel pattern CP1. The first interlayer IL1 may be located between the second storage contact SC2 and the second channel pattern CP2. The first interlayer IL1 may cover the upper surfaces of the first and second storage contacts SC1 and SC2. In other words, the first interlayer IL1 may overlap the first and second storage contacts SC1 and SC2 in the third direction DR3.

For example, the first interlayer IL1 may be located between the first storage contact SC1 and the first horizontal portion CP1b of the first channel pattern CP1. The first interlayer IL1 may overlap the first horizontal portion CP1b of the first channel pattern CP1 in the third direction DR3. The first interlayer IL1 may be located between the second storage contact SC2 and the second horizontal portion CP2b of the second channel pattern CP2. The first interlayer IL1 may overlap the second horizontal portion CP2b of the second channel pattern CP2 in the third direction DR3.

For example, a thickness of the first interlayer IL1 may be about 0.5 nm or more, for example, about 0.6 nm or more, about 0.7 nm or more, about 0.8 nm or more, about 0.9 nm or more, about 1.0 nm or more, about 1.5 nm or more, about 2.0 nm or more, or about 2.5 nm or more, and the thickness of the first interlayer IL1 may be about 3.0 nm or less, for example, about 2.9 nm or less, about 2.8 nm or less, about 2.7 nm or less, about 2.6 nm or less, about 2.5 nm or less, about 2.0 nm or less, about 1.5 nm or less, or about 1.0 nm or less. For example, the thickness of the first interlayer IL1 may be about 0.5 nm to about 3.0 nm.

For example, the sheet resistance (Rₛₕₑₑₜ, unit: ohm/sq) of the first interlayer IL1 may be smaller than the sheet resistance of the insulating layer and larger than the sheet resistance of the metal layer. For example, the sheet resistance of the first interlayer IL1 may be smaller than the sheet resistance of the gate insulating pattern GI and larger than the sheet resistances of the first storage contact SC1 and the second storage contact SC2. The sheet resistance of the first interlayer IL1 may be smaller than the sheet resistance of the gate insulating pattern GI and larger than the sheet resistances of the first storage contact SC1 and the second storage contact SC2. In this case, the first interlayer IL1 may reduce the contact resistance between the first and second channel patterns CP1 and CP2 and the first and second storage contacts SC1 and SC2 and maximize the on-current (Iₒₙ) enhancement.

Here, the surface resistance may be measured seven times using the 4-point probe method using Mitsubishi Ioresta-GP (MCP-T610) and ESP type probes (MCP-TP08P), and then obtaining an average value. At this time, the unit area may be 1 cm×1 cm, 1 μm×1 μm, 100 nm×100 nm, 10 nm×10 nm, or 1 nm×1 nm.

The first interlayer IL1 may include an oxide having a surface resistance smaller than that of the insulating material and larger than that of the metal. For example, the first interlayer IL1 may include AlOₓ (0<x≤1.5), TiOₓ (0<x≤2), ZnO, C-axis aligned crystalline indium gallium zinc oxide (CAAC-IGZO), or a combination thereof.

Meanwhile, in a structure in which the first and second channel patterns CP1 and CP2 have first and second horizontal portions CP1b and CP2b, respectively, and a first interlayer IL1 is inserted between the first and second horizontal portions CP1b and CP2b of the first and second channel patterns CP1 and CP2 and the first and second storage contacts SC1 and SC2, when the first and second channel patterns CP1 and CP2 are formed first and then the first and second word lines WL1 and WL2 are formed later, the first and second horizontal portions CP1b and CP2b of the first and second channel patterns CP1 and CP2 extend in a direction approaching the first and second word lines WL1 and WL2, so that as the first and second horizontal portions CP1b and CP2b of the first and second channel patterns CP1 and CP2 and the first and second word lines WL1 and WL2 overlap in the third direction DR3, it may be difficult to secure an effective separation distance from a field perspective between the first and second horizontal portions CP1b and CP2b of the first and second channel patterns CP1 and CP2 and the first and second word lines WL1 and WL2.

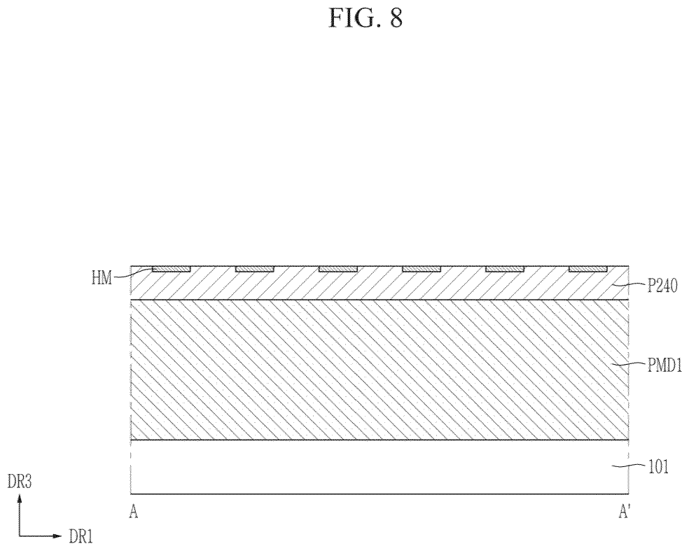

On the other hand, as described later in FIGS. 8 to 39, when the first and second word lines WL1 and WL2 are formed first and the first and second channel patterns CP1 and CP2 are formed later, the first and second horizontal portions CP1b and CP2b of the first and second channel patterns CP1 and CP2 extend in a direction away from the first and second word lines WL1 and WL2, so that the first and second horizontal portions CP1b and CP2b of the first and second channel patterns CP1 and CP2 and the first and second word lines WL1 and WL2 do not overlap in the third direction DR3, thereby securing an effective separation distance from a field perspective between the first and second horizontal portions CP1b and CP2b of the first and second channel patterns CP1 and CP2 and the first and second word lines WL1 and WL2.

In an embodiment, when the first and second word lines WL1 and WL2 are formed first and the first and second channel patterns CP1 and CP2 are formed and CP2 may be formed continuously without etching, thereby preventing damage to the interface between the gate insulating pattern GI and the first and second channel patterns CP1 and CP2 due to etching.

Accordingly, the first horizontal portion CP1b of the first channel pattern CP1 may extend in the first direction DR1 from the lower end of the first vertical portion CP1a, but may extend in a direction away from the first word line WL1. For example, the first vertical portion CP1a of the first channel pattern CP1 may have a first surface facing the first word line WL1 and a second surface facing the second insulating pattern MD2 described later, and the first horizontal portion CP1b of the first channel pattern CP1 may be connected to a second surface of the first vertical portion CP1a and may extend in a first direction DR1 away from the second surface of the first vertical portion CP1a. The first horizontal portion CP1b of the first channel pattern CP1 does not overlap the first word line WL1 in the third direction DR3.

The second horizontal portion CP2b of the second channel pattern CP2 may extend in the first direction DR1 from the lower end of the second vertical portion CP2a, but may extend in a direction away from the second word line WL2. For example, the second vertical portion CP2a of the second channel pattern CP2 may have a first surface facing the second insulating pattern MD2 and a second surface facing the second word line WL2, and the second horizontal portion CP2b of the second channel pattern CP2 may be connected to the first surface of the second vertical portion CP2a and may extend in a first direction DR1 away from the first surface of the second vertical portion CP2a. The second horizontal portion CP2b of the second channel pattern CP2 does not overlap the second word line WL2 in the third direction DR3.

In other words, the first horizontal portion CP1b of the first channel pattern CP1 and the second horizontal portion CP2b of the second channel pattern CP2 may extend in the first direction DR1, but may extend in opposite directions. For example, in a cross-section (e.g., FIG. 2) cut in the first direction DR1 and the third direction DR3, the first horizontal portion CP1b of the first channel pattern CP1 may extend to the left in the first direction DR1, and the second horizontal portion CP2b of the second channel pattern CP2 may extend to the right in the first direction DR1.

As the first horizontal portion CP1b of the first channel pattern CP1 extends in the first direction DR1 from the lower end of the first vertical portion CP1a and the first horizontal portion CP1b of the first channel pattern CP1 overlaps the first storage contact SC1 in the third direction DR3, the first vertical portion CP1a of the first channel pattern CP1 may be located closer to the first word line WL1 with respect to (or than to) the middle point of the first storage contact SC1 in the first direction DR1. For example, the first storage contact SC1 may have a first surface located closer to the first insulating pattern MD1 and a second surface located closer to the second insulating pattern MD2, and the first vertical portion CP1a of the first channel pattern CP1 may be located closer to the first surface in the first direction DR1 than to the second surface of the first storage contact SC1.

As the first horizontal portion CP2b of the second channel pattern CP2 extends in the first direction DR1 from the lower end of the second vertical portion CP2a and the second horizontal portion CP2b of the second channel pattern CP2 overlaps the second storage contact SC2 in the third direction DR3, the second vertical portion CP2a of the second channel pattern CP2 may be located closer to the second word line WL2 with respect to the middle point of the second storage contact SC2 in the first direction DR1. For example, the second storage contact SC2 may have a first surface located closer to the first insulating pattern MD1 and a second surface located closer to the second insulating pattern MD2, and a second vertical portion CP2a of the second channel pattern CP2 may be located closer to the first surface in the first direction DR1 than to the second surface of the second storage contact SC2.

When the first and second vertical portions CP1a and CP2a of the first and second channel patterns CP1 and CP2 are located at the middle points of the first and second storage contacts SC1 and SC2 in the first direction DR1, the width of the first insulating pattern MD1 in the first direction DR1 combined with the thickness of the gate insulating pattern GI may be almost similar to the width of the second insulating pattern MD2 in the first direction DR1, but since the first and second vertical portions CP1a and CP2a of the first and second channel patterns CP1 and CP2 are located closer to the first and second word lines WL1 and WL2 with respect to the middle point of the first direction DR1 of the first and second storage contacts SC1 and SC2, the width of the first insulating pattern MD1 in the first direction DR1 may be smaller than the width of the second insulating pattern MD2 in the first direction DR1.

The semiconductor device may further include a second insulating pattern MD2 located between a plurality of first insulating patterns MD1. The semiconductor device may include a plurality of second insulating patterns MD2. A plurality of second insulating patterns MD2 may be spaced apart from each other along the first direction DR1.

The second insulating pattern MD2 may include a gap-fill insulating layer MD2a and an insulating liner MD2b located on both sides of the gap-fill insulating layer MD2a.

The gap-fill insulating layer MD2a may be located to fill the space between adjacent first insulating patterns MD1. The gap-fill insulating layer MD2a may be located approximately at the center of the second insulating pattern MD2 in the first direction DR1. In other words, the gap-fill insulating layer MD2a may be located approximately at the center of the space between adjacent first insulating patterns MD1.

The insulating liner MD2b may be separated from each other on both sides of the gap-fill insulating layer MD2a. The insulating liner MD2b may be located between the first channel pattern CP1 and the gap-fill insulating layer MD2a, and may be located between the second channel pattern CP2 and the gap-fill insulating layer MD2a.

The upper surface of the insulating liner MD2b may be located at a different level from the upper surfaces of the first channel pattern CP1 and the second channel pattern CP2. The upper surface of the insulating liner MD2b may be located at a higher level than the upper surface of the first channel pattern CP1. The upper surface of the insulating liner MD2b may be located at a higher level than the upper surface of the second channel pattern CP2. The upper surface of the insulating liner MD2b may be located at substantially the same level as the upper surface of the gap-fill insulating layer MD2a.

The first word line WL1 and a first channel pattern CP1 may be located between the first insulating pattern MD1 and one of the second insulating patterns MD2. The first channel pattern CP1 may be located between the gate insulating pattern GI and the second insulating pattern MD2. The first vertical portion CP1a of the first channel pattern CP1 may be located between the gate insulating pattern GI and the second insulating pattern MD2.

The side and lower surfaces of the second insulating pattern MD2 may be in contact with the first channel pattern CP1. A side surface of the second insulating pattern MD2 may be in contact with a first vertical portion CP1a of the first channel pattern CP1, and a lower surface of the second insulating pattern MD2 may be in contact with a horizontal portion CP1b of the first channel pattern CP1. The first vertical portion CP1a of the first channel pattern CP1 may be in contact with the side surface of the insulating liner MD2b of the second insulating pattern MD2. The horizontal portion CP1b of the first channel pattern CP1 may be in contact with the lower surface of the insulating liner MD2b of the second insulating pattern MD2. In other words, the insulating liner MD2b of the second insulating pattern MD2 may be located on the first horizontal portion CP1b of the first channel pattern CP1. The insulating liner MD2b of the second insulating pattern MD2 may overlap the first horizontal portion CP1b of the first channel pattern CP1 in the third direction DR3 and may overlap the first storage contact SC1 in the third direction DR3.

The second word line WL2 and the second channel pattern CP2 may be located between the first insulating pattern MD1 and another second insulating pattern MD2. The second channel pattern CP2 may be located between the gate insulating pattern GI and the second insulating pattern MD2. The first vertical portion CP2a of the second channel pattern CP2 may be located between the gate insulating pattern GI and the second insulating pattern MD2.

The side and lower surfaces of the second insulating pattern MD2 may be in contact with the second channel pattern CP2. A side surface of the second insulating pattern MD2 may be in contact with a first vertical portion CP2a of the second channel pattern CP2, and a lower surface of the second insulating pattern MD2 may be in contact with a horizontal portion CP2b of the second channel pattern CP2. The first vertical portion CP2a of the second channel pattern CP2 may be in contact with the side surface of the insulating liner MD2b of the second insulating pattern MD2. The horizontal portion CP2b of the second channel pattern CP2 may be in contact with the lower surface of the insulating liner MD2b of the second insulating pattern MD2. In other words, the insulating liner MD2b of the second insulating pattern MD2 may be located on the second horizontal portion CP2b of the second channel pattern CP2. The insulating liner MD2b of the second insulating pattern MD2 may overlap the second horizontal portion CP2b of the second channel pattern CP2 in the third direction DR3 and may overlap the second storage contact SC2 in the third direction DR3.

The second insulating pattern MD2 may include an insulating material. For example, the second insulating pattern MD2 may include silicon oxide, silicon nitride, silicon oxynitride, a high-k material having a higher dielectric constant than silicon oxide, or a combination thereof. The gap-fill insulating layer MD2a and the insulating liner MD2b constituting the second insulating pattern MD2 may include different materials. For example, the gap-fill insulating layer MD2a may include silicon oxide, and the insulating liner MD2b may include a high-k material such as Al₂O₃. However, this is only one example, and the materials of the gap-fill insulating layer MD2a and the insulating liner MD2b may be changed in various ways.

The bit line BL may be located on the first channel pattern CP1 and the second channel pattern CP2. The bit line BL may be in contact with the first channel pattern CP1 and the second channel pattern CP2. The bit line BL may extend along the first direction DR1. A plurality of bit lines BL may be spaced apart along the second direction DR2. Each bit line BL may be connected to a plurality of first channel patterns CP1 and a plurality of second channel patterns CP2. The first channel pattern CP1 and the second channel pattern CP2 may be alternately and repeatedly located along the first direction DR1. The bit line BL may be connected to a plurality of first channel patterns CP1 and a plurality of second channel patterns CP2 located spaced apart from each other along a first direction DR1.

The bit line BL may have an extension portion BLa, a first protrusion portion BLb1, and a second protrusion portion BLb2. The extension portion BLa of the bit line BL may be located over the first channel pattern CP1 and the second channel pattern CP2. The extension portion BLa of the bit line BL may extend along the first direction DR1.

The first protrusion portion BLb1 of the bit line BL may protrude in a third direction DR3 from the extension portion BLa toward the first channel pattern CP1. The first protrusion portion BLb1 of the bit line BL may be located on the upper surface of the first channel pattern CP1. The first protrusion portion BLb1 of the bit line BL may be in contact with the upper surface of the first channel pattern CP1. The first protrusion portion BLb1 of the bit line BL may protrude into a space between the gate insulating pattern GI and the insulating liner MD2b of the second insulating pattern MD2.

The second protrusion portion BLb2 of the bit line BL may protrude in a third direction DR3 from the extension portion BLa toward the second channel pattern CP2. The second protrusion portion BLb2 of the bit line BL may be located on the upper surface of the second channel pattern CP2. The second protrusion portion BLb2 of the bit line BL may be in contact with the upper surface of the second channel pattern CP2. The second protrusion portion BLb2 of the bit line BL may protrude into the space between the gate insulating pattern GI and the insulating liner MD2b of the second insulating pattern MD2.

The upper surface of the first channel pattern CP1 may be located at a lower level than the upper surface of the gate insulating pattern GI, the upper surface of the second insulating pattern MD2, or the upper surface of the gate capping pattern 241. The upper surface of the gate insulating pattern GI, the upper surface of the second insulating pattern MD2, or the upper surface of the gate capping pattern 241 may be located at substantially the same level as the lower surface of the extension portion BLa of the bit line BL. The first protrusion portion BLb1 of the bit line BL may be located between the upper surface of the first channel pattern CP1 and the lower surface of the extension portion BLa of the bit line BL.

The upper surface of the second channel pattern CP2 may be located at a lower level than the upper surface of the gate insulating pattern GI, the upper surface of the second insulating pattern MD2, or the upper surface of the gate capping pattern 241. The upper surface of the gate insulating pattern GI, the upper surface of the second insulating pattern MD2, or the upper surface of the gate capping pattern 241 may be located at substantially the same level as the lower surface of the extension portion BLa of the bit line BL. The second protrusion portion BLb2 of the bit line BL may be located between the upper surface of the second channel pattern CP2 and the lower surface of the extension portion BLa of the bit line BL.

The width of the extension portion BLa of the bit line BL along the second direction DR2 may be smaller than the width of the first channel pattern CP1 along the second direction DR2. The width of the extension portion BLa of the bit line BL along the second direction DR2 may be smaller than the width of the second channel pattern CP2 along the second direction DR2. By ensuring sufficient spacing between adjacent bit lines BLs, interference between bit lines BLs may be minimized.

The width of the first protrusion portion BLb1 of the bit line BL along the second direction DR2 may be substantially the same as the width of the first channel pattern CP1 along the second direction DR2. The width of the second protrusion portion BLb2 of the bit line BL along the second direction DR2 may be substantially the same as the width of the second channel pattern CP2 along the second direction DR2.

The gate insulating pattern GI may be located between a first protrusion portion BLb1 of a bit line BL and a first word line WL1. The first protrusion portion BLb1 of the bit line BL may be spaced apart from the first word line WL1 with the gate insulating pattern GI interposed therebetween. The gate insulating pattern GI may be located between the second protrusion portion BLb2 of the bit line BL and the second word line WL2. The second protrusion portion BLb2 of the bit line BL may be spaced apart from the second word line WL2 with the gate insulating pattern GI interposed therebetween.

The bit line BL may include doped polysilicon, a metal, a conductive metal nitride, a conductive metal silicide, a conductive metal oxide, or a combination thereof. For example, the bit line BL may include, but is not limited to, Al, Cu, Ti, Ta, Ru, W, Mo, Pt, Ni, Co, TiN, TaN, WN, NbN, TiAlN, TiSi, TiSiN, TaSi, TaSiN, RuTiN, NiSi, CoSi, IrOx (0<x≤2), RuOₓ (0<x≤2), or a combination thereof.

The semiconductor device may further include a bit line capping layer 260 located on a bit line BL, and a shield pattern BLS located on the bit line capping layer 260.

The bit line capping layer 260 may cover the upper surface and side surfaces of the bit line BL. The bit line capping layer 260 may be located on the gap-fill insulating layer MD2a, the first channel pattern CP1, and the second channel pattern CP2. The bit line capping layer 260 may cover the upper surfaces of the gap-fill insulating layer MD2a, the first channel pattern CP1, and the second channel pattern CP2 between the bit lines BL. The bit line capping layer 260 may include a lower layer 262 and an upper layer 264. The upper layer 264 may be located above the lower layer 262.

The bit line capping layer 260 may include an insulating material. For example, the bit line capping layer 260 may include silicon oxide, silicon nitride, silicon oxynitride, or a combination thereof. The lower layer 262 and the upper layer 264 constituting the bit line capping layer 260 may include different materials. For example, the lower layer 262 may include silicon nitride and the upper layer 264 may include silicon oxide.

The shield pattern BLS may be located on the bit line capping layer 260. The shield pattern BLS may be separated from the bit line BL by a bit line capping layer 260. The shield pattern BLS may overlap the bit line BL in the third direction DR3. The shield pattern BLS may also overlap the space between bit lines BL in the third direction DR3. The shield pattern BLS may be located between multiple bit lines BLs. The shield pattern BLS may overlap the bit line BL in the second direction DR2. The shield pattern BLS may reduce disturbance and parasitic capacitance between bit lines BLs. Accordingly, the delay (RC-delay) of the signal applied to the bit line BL may be reduced, and the operating speed of the semiconductor device may be improved.

The shield pattern BLS may include doped polysilicon, a metal, a conductive metal nitride, a conductive metal oxide, or a combination thereof. For example, the shield pattern BLS may include, but is not limited to, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx (0<x≤2), RuOₓ (0<x≤2), or a combination thereof.

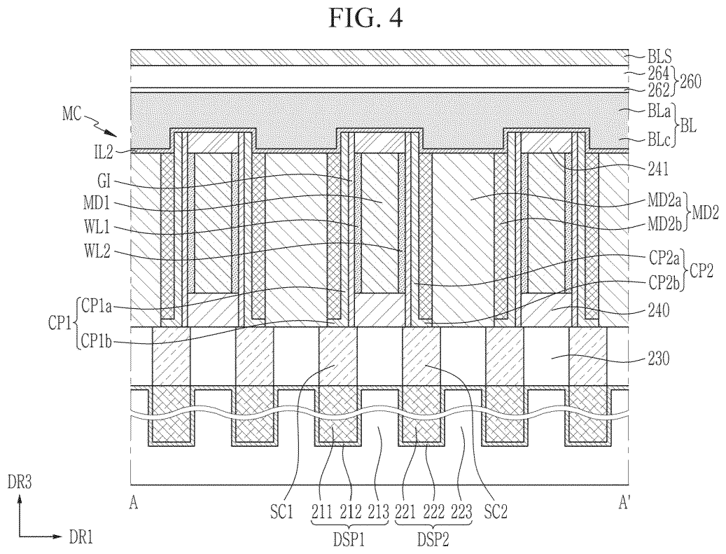

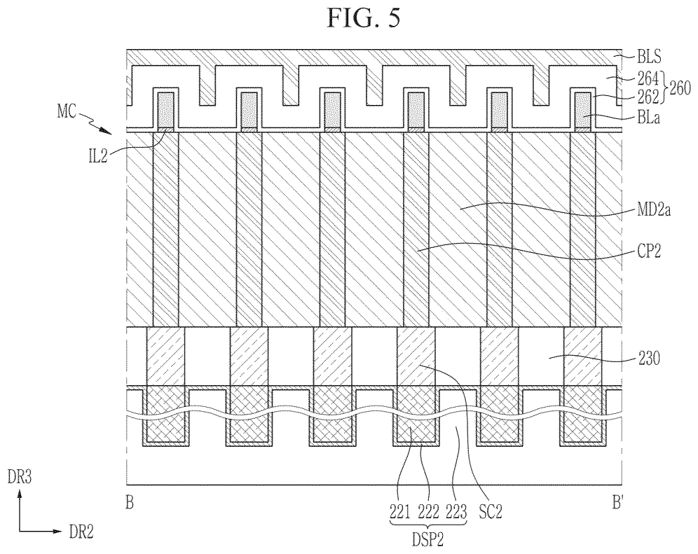

FIGS. 4 and 5 are cross-sectional views showing a semiconductor device according to an embodiment, corresponding to FIGS. 2 and 3, respectively.

The embodiments illustrated in FIGS. 4 and 5 are substantially the same as the embodiments illustrated in FIGS. 2 and 3, and thus a description thereof will be omitted and the differences will be mainly explained. In an embodiment, the same drawing symbols are used for the same components as in the previous embodiment.

In FIGS. 2 and 3, the bit line BL is illustrated as having an extension portion BLa located on a first channel pattern CP1 and a second channel pattern CP2 and extending in a first direction DR1, a first protrusion portion BLb1 protruding in a third direction DR3 from the extension portion BLa toward the first channel pattern CP1, and a second protrusion portion CLb2 protruding in the third direction DR3 from the extension portion BLa toward the second channel pattern CP2.

Referring to FIGS. 4 and 5, the bit line BL may have an extension portion BLa and a third protrusion portion BLc. The extension portion BLa of the bit line BL may be located on the first channel pattern CP1 and the second channel pattern CP2. The extension portion BLa of the bit line BL may extend along the first direction DR1.

The third protrusion portion BLc of the bit line BL may protrude in a third direction DR3 from the extension portion BLa toward the second insulating pattern MD2. The third protrusion portion BLc of the bit line BL may be located on the upper surface of the second insulating pattern MD2. The third protrusion portion BLc of the bit line BL may be in contact with the upper surface of the second insulating pattern MD2. For example, the third protrusion portion BLc of the bit line BL may be in contact with the upper surface of the insulating liner MD2b of the second insulating pattern MD2. The third protrusion portion BLc of the bit line BL may be in contact with the upper surface of the gap-fill insulating layer MD2a of the second insulating pattern MD2.

The third protrusion portion BLc of the bit line BL may protrude into the space between the first channel pattern CP1 and the second channel pattern CP2. The third protrusion portion BLc of the bit line BL may cover the side surface of the first channel pattern CP1, the side surface of the second channel pattern CP2, and the upper surface of the second insulating pattern MD2. The third protrusion portion BLc of the bit line BL may extend in the first direction DR1 from the side of the first channel pattern CP1 to the side of the second channel pattern CP2 along the upper surface of the second insulating pattern MD2.

The upper surface of the second insulating pattern MD1 may be located at a lower level than the upper surface of the first channel pattern CP1, the upper surface of the second channel pattern CP2, the upper surface of the gate insulating pattern GI, or the upper surface of the gate capping pattern 241. The upper surface of the first channel pattern CP1, the upper surface of the second channel pattern CP2, the upper surface of the gate insulating pattern GI, or the upper surface of the gate capping pattern 241 may be located at substantially the same level as the lower surface of the extension portion BLa of the bit line BL. The third protrusion portion BLc of the bit line BL may be located between the upper surface of the second insulating pattern MD1 and the lower surface of the extension portion BLa of the bit line BL.

The gate insulating pattern GI may be located between the third protrusion portion BLc of the bit line BL and the first word line WL1. The first protrusion portion BLb1 of the bit line BL may be spaced apart from the first word line WL1 with the gate insulating pattern GI interposed therebetween. The gate insulating pattern GI may be located between the third protrusion portion BLc of the bit line BL and the second word line WL2. The third protrusion portion BLc of the bit line BL may be spaced apart from the second word line WL2 with the gate insulating pattern GI interposed therebetween.

In a vertical channel transistor (VCT) structure, as the contact area between the first and second channel patterns CP1 and CP2 and the bit line BL decreases exponentially, there is a need to improve the contact resistance. The contact area between the first and second channel patterns CP1 and CP2 and the bit line BL may be improved by having the bit line BL have a third protrusion portion BLc protruding toward the first and second channel patterns CP1 and CP2.

In an embodiment, by inserting a second interlayer IL2 between the first and second channel patterns CP1 and CP2 and the bit line BL, the contact resistance may be reduced and the on-current (Iₒₙ) enhancement may be maximized.

The second interlayer IL2 may be located between the bit line BL and the first channel pattern CP1. The second interlayer IL2 may be located between the bit line BL and the second channel pattern CP2. The second interlayer IL2 may extend in the first direction DR1 along the bit line BL. A plurality of second interlayers IL2 may be spaced apart along the second direction DR2. Each second interlayer IL2 may be connected to a plurality of first channel patterns CP1 and a plurality of second channel patterns CP2. The first channel pattern CP1 and the second channel pattern CP2 may be alternately and repeatedly located along the first direction DR1. The second interlayer IL2 may be connected to a plurality of first channel patterns CP1 and a plurality of second channel patterns CP2 located spaced apart from each other along the first direction DR1. In other words, the second interlayer IL2 may overlap the bit line BL in the third direction DR3.

The second interlayer IL2 may be located between the first channel pattern CP1, the second channel pattern CP2, the gate insulating pattern GI, the gate capping pattern 241, the second insulating pattern MD2, or a combination thereof, and the bit line BL. For example, the second interlayer IL2 may be located between the upper surface of the first channel pattern CP1, the upper surface of the second channel pattern CP2, the upper surface of the gate insulating pattern GI, the upper surface of the gate capping pattern 241, or a combination thereof, and the extension portion BLa of the bit line BL.

In an embodiment, since the bit line BL includes the third protrusion portion BLc, the second interlayer IL2 may be located between the side surface of the first channel pattern CP1, the side surface of the second channel pattern CP2, the upper surface of the second insulating pattern MD2, or a combination thereof, and the third protrusion portion BLc of the bit line BL.

For example, the thickness of the second interlayer IL2 may be about 0.5 nm or more, for example, about 0.6 nm or more, about 0.7 nm or more, about 0.8 nm or more, about 0.9 nm or more, about 1.0 nm or more, about 1.5 nm or more, about 2.0 nm or more, or about 2.5 nm or more, and the thickness of the second interlayer IL2 may be about 3.0 nm or less, for example, about 2.9 nm or less, about 2.8 nm or less, about 2.7 nm or less, about 2.6 nm or less, about 2.5 nm or less, about 2.0 nm or less, about 1.5 nm or less, or about 1.0 nm or less. For example, the thickness of the second interlayer IL2 may be about 0.5 nm to about 3.0 nm.

For example, the sheet resistance (Rₛₕₑₑₜ, unit: ohm/sq) of the second interlayer IL2 may be smaller than the sheet resistance of the insulating layer and larger than the sheet resistance of the metal layer. For example, the sheet resistance of the second interlayer IL2 may be smaller than the sheet resistance of the gate insulating pattern GI and larger than the sheet resistance of the bit line BL. The sheet resistance of the second interlayer IL2 may be smaller than the sheet resistance of the gate insulating pattern GI and larger than the sheet resistance of the bit line BL. In this case, the second interlayer IL2 may reduce the contact resistance between the first and second channel patterns CP1 and CP2 and the bit line BL and maximize the on-current (Iₒₙ) enhancement.

Here, the surface resistance may be measured seven times using the 4-point probe method using Mitsubishi Ioresta-GP (MCP-T610) and ESP type probes (MCP-TP08P), and then obtaining an average value. At this time, the unit area may be 1 cm×1 cm, 1 μm×1 μm, 100 nm×100 nm, 10 nm×10 nm, or 1 nm×1 nm.

The second interlayer IL2 may include an oxide having a surface resistance smaller than that of the insulating material and larger than that of the metal. For example, the second interlayer IL2 may include AlOₓ (0<x≤1.5), TiOₓ (0<x≤2), ZnO, C-axis aligned crystalline indium gallium zinc oxide (CAAC-IGZO), or a combination thereof.

Meanwhile, in a structure in which the bit line BL has a third protrusion portion BLc and the second interlayer IL2 is inserted between the first and second channel patterns CP1 and CP2 and the bit line BL, when the first and second channel patterns CP1 and CP2 are formed first and the first and second word lines WL1 and WL2 are formed later, it may be difficult to secure a sufficient separation distance between the bit line BL and the first and second word lines WL1 and WL2 as the third protrusion portion BLc of the bit line BL protrudes toward the first and second word lines WL1 and WL2.

On the other hand, as described later in FIGS. 8 to 39, when the first and second word lines WL1 and WL2 are formed first and the first and second channel patterns CP1 and CP2 are formed later, a sufficient separation distance may be secured between the bit line BL and the first and second word lines WL1 and WL2 by making the bit line BL such that the third protrusion portion BLc is located far from the first and second word lines WL1 and WL2 with the first and second channel patterns CP1 and CP2 interposed therebetween.

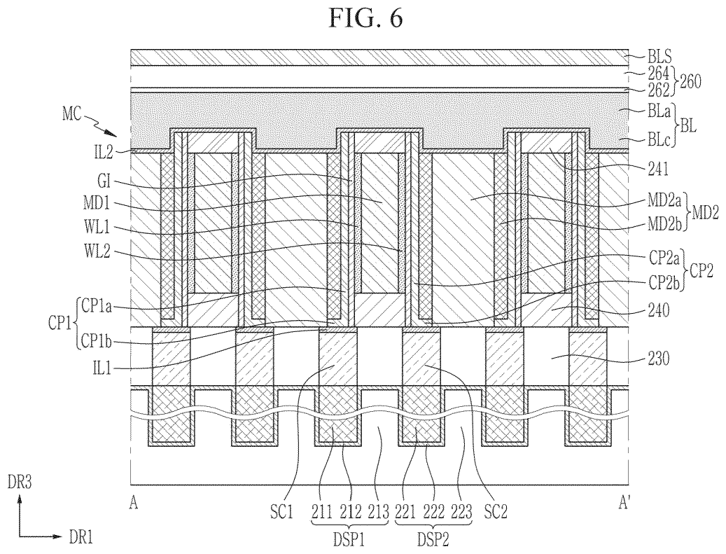

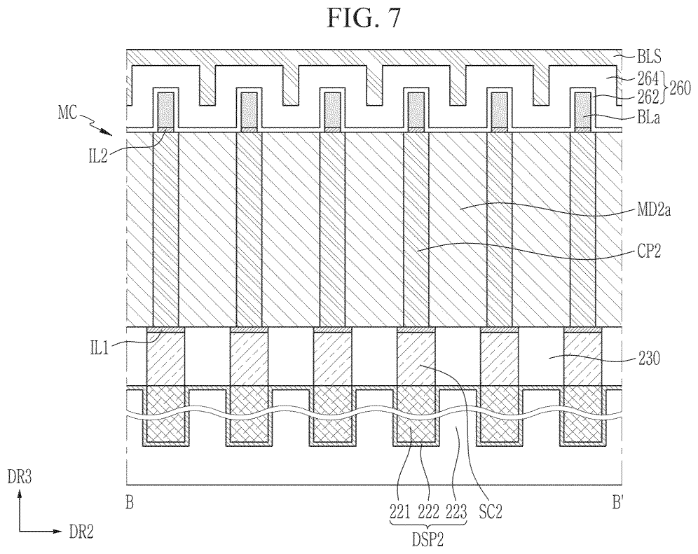

FIGS. 6 and 7 are cross-sectional views showing a semiconductor device according to an embodiment, corresponding to FIGS. 2 and 3, respectively.

The embodiments illustrated in FIGS. 6 and 7 are substantially the same as the embodiments illustrated in FIGS. 2 to 5, and thus a description thereof will be omitted and the differences will be mainly described. In an embodiment, the same drawing symbols are used for the same components as in the previous embodiment.

In FIGS. 2 and 3, the first interlayer IL1 is illustrated as being located (or as provided) between the first storage contact SC1 and the first channel pattern CP1, and the first interlayer IL1 is illustrated as being located (or as provided) between the second storage contact SC2 and the second channel pattern CP2.

In FIGS. 4 and 5, the second interlayer IL2 is illustrated as being located (or as provided) between the bit line BL and the first channel pattern CP1, and the second interlayer IL2 is illustrated as being located (or as provided) between the bit line BL and the second channel pattern CP2.

In FIGS. 6 and 7, a case is illustrated where the semiconductor device includes both a first interlayer IL1 and a second interlayer IL2. In other words, the first interlayer IL1 may be located between the first storage contact SC1 and the first channel pattern CP1, and the first interlayer IL1 may be located between the second storage contact SC2 and the second channel pattern CP2. The second interlayer IL2 may be located between the bit line BL and the first channel pattern CP1, and a second interlayer IL2 may be located between the bit line BL and the second channel pattern CP2.

Hereinafter, a method for manufacturing a semiconductor device according to an embodiment will be described with reference to FIGS. 8 to 39. In addition, reference may be made to FIGS. 1 to 3 described above.

FIGS. 8 to 39 are cross-sectional views showing a method of manufacturing a semiconductor device according to a process sequence of the embodiments.

FIG. 8 is a drawing corresponding to a cross-sectional view taken along line A-A′ of FIG. 1. At this time, the drawing corresponding to the cross-sectional view taken along the B-B′ line of FIG. 1 may be the same as FIG. 8, and thus it is omitted.

Referring to FIG. 8, a first insulating material layer PMD1 and a storage capping material layer P240 are formed on a first substrate 101.

The first substrate 101 may include a semiconductor material. For example, the first substrate 101 may include a Group IV semiconductor, a Group III-V compound semiconductor, a Group II-VI compound semiconductor, etc. For example, the first substrate 101 may include a semiconductor such as Si, Ge, or a compound semiconductor such as SiGe, SiC, GaAs, InAs, or InP. However, the material of the first substrate 101 is not limited to those materials and may be changed in various ways.

The first insulating material layer PMD1 and the storage capping material layer P240 may include different insulating materials. The storage capping material layer P240 and the first insulating material layer PMD1 may have different etch rates. For example, the storage capping material layer P240 may include silicon nitride, and the first insulating material layer PMD1 may include silicon oxide. However, embodiments of the disclosure are not limited to the above embodiment, and the materials of the storage capping material layer P240 and the first insulating material layer PMD1 may be variously changed.

For example, the first insulating material layer PMD1 may be formed by thermal oxidation of the first substrate 101, and the storage capping material layer P240 may be formed by depositing an insulating material on the first insulating material layer PMD1.

Next, a mask pattern HM is formed on the storage capping material layer P240.

For example, a mask material layer is laminated on a storage capping material layer P240. The mask material layer may be formed using a material having an etching selectivity with respect to the material of the first interlayer IL1, or using a carbon-based material. When using a carbon-based material, the mask material layer may be formed by coating a spin on hard mask or depositing an amorphous carbon layer. The mask pattern HM may be formed by patterning a mask material layer. In an embodiment, after depositing an insulating material on the mask pattern HM, the insulating material may be etched until the mask pattern HM is revealed, thereby forming the mask pattern HM buried in the storage capping material layer P240.

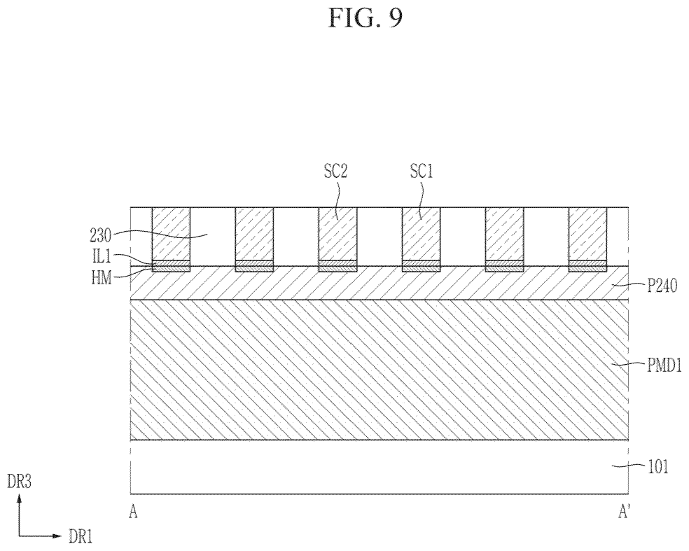

FIG. 9 is a drawing corresponding to a cross-sectional view taken along line A-A′ of FIG. 1. At this time, the drawing corresponding to the cross-sectional view taken along the line B-B′ of FIG. 1 may be the same as FIG. 9, and thus it is omitted.

Referring to FIG. 9, a first interlayer IL1, a first storage contact SC1, and a second storage contact SC2 are formed on a storage capping material layer P240.

For example, a first interface material layer and a conductive material layer are sequentially laminated on a storage capping material layer P240. The first interface material layer may be formed by depositing AlOₓ (0<x≤1.5), TiOₓ (0<x≤2), ZnO, C-axis aligned crystalline indium gallium zinc oxide (CAAC-IGZO), or a combination thereof. The conductive material layer may be formed by depositing a conductive material such as doped polysilicon, a metal, a conductive metal nitride, or a conductive metal oxide.

Next, the first interface material layer and the conductive material layer may be patterned to form the first interlayer IL1, the first storage contact SC1, and the second storage contact SC2.

A second interlayer insulating layer 230 may be further formed between the first storage contact SC1 and the second storage contact SC2. An insulating material such as silicon oxide, silicon nitride, or silicon oxynitride may be deposited on the first storage contact SC1 and the second storage contact SC2. Thereafter, when a planarization process is performed, the insulating material located on the upper surfaces of the first storage contact SC1 and the second storage contact SC2 may be removed, and the insulating material located between the first storage contact SC1 and the second storage contact SC2 may remain to form a second interlayer insulating layer 230. The upper surface of the second interlayer insulating layer 230 may be located at the same level as the upper surfaces of the first storage contact SC1 and the second storage contact SC2.

For example, it has been described that the mask pattern HM and the first interlayer IL1 are formed in different processes, but this is not limited to this, and the patterning of the mask pattern HM and the first interlayer IL1 may be performed in the same process. For example, after sequentially stacking a mask material layer, a first interface material layer, and a conductive material layer on a storage capping material layer P240, the mask material layer, the first interface material layer, and the conductive material layer may be simultaneously patterned to form a mask pattern HM, a first interlayer IL1, a first storage contact SC1, and a second storage contact SC2.

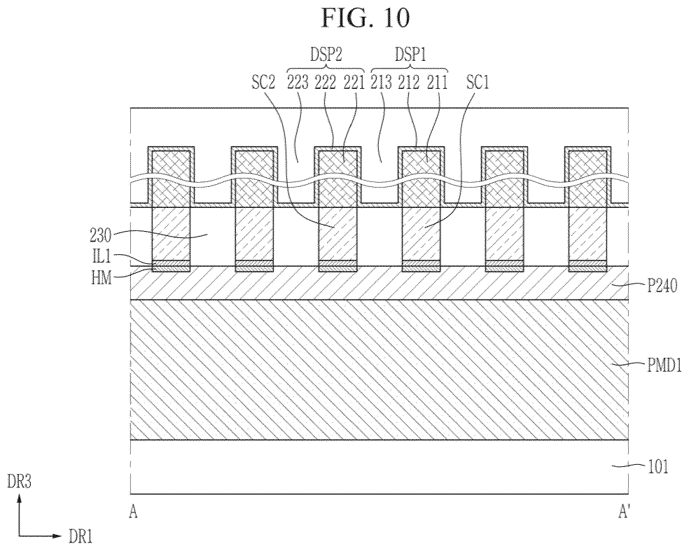

FIG. 10 is a drawing corresponding to a cross-sectional view taken along line A-A′ of FIG. 1. At this time, the drawing corresponding to the cross-sectional view taken along the B-B′ line of FIG. 1 may be the same as FIG. 10, so it is omitted.

Referring to FIG. 10, a first data storage pattern DSP1 and a second data storage pattern DSP2 are formed on a first storage contact SC1 and a second storage contact SC2.

For example, a conductive material may be deposited on the first storage contact SC1, the second storage contact SC2, and the second interlayer insulating layer 230, and patterned to form first capacitor electrodes 211 and 221 on the first storage contact SC1 and the second storage contact SC2. Next, by depositing an insulating material and a conductive material, dielectric layers 212 and 222 and second capacitor electrodes 213 and 223 may be formed.

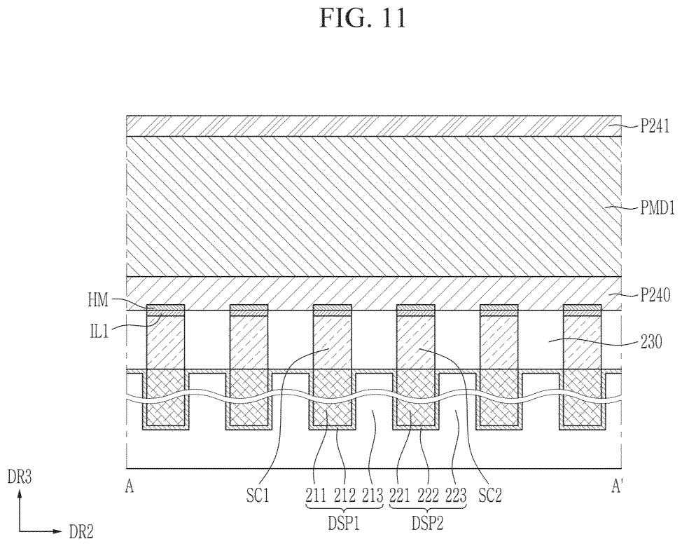

FIG. 11 is a drawing corresponding to a cross-sectional view taken along line A-A′ of FIG. 1. At this time, the drawing corresponding to the cross-sectional view taken along the B-B′ line of FIG. 1 may be the same as FIG. 11, and thus it is omitted.

Referring to FIG. 11, the upper surfaces of the first data storage pattern DSP1 and the second data storage pattern DSP2 are rotated so that they become the lower surfaces.

For example, the rotated first data storage pattern DSP1 and the second data storage pattern DSP2 may be located on a carrier substrate. The upper surfaces of the first data storage pattern DSP1 and the second data storage pattern DSP2 may be located to face the carrier substrate and then attached to the carrier substrate. An adhesive member may be placed between the first data storage pattern DSP1 and the second data storage pattern DSP2 and the carrier substrate.

The carrier substrate may have substantially the same area as the first data storage pattern DSP1 and the second data storage pattern DSP2, or may have a larger area than the first data storage pattern DSP1 and the second data storage pattern DSP2. The carrier substrate may be, for example, a semiconductor wafer, a ceramic substrate, or a glass substrate.

The adhesive member may include a base film and an adhesive layer attached to both surfaces of the base film. The base film may be, for example, a polyethylene-based film such as polyethylene terephthalate (PET) or polyethylene-2,6-naphthalenedicarboxylate (PEN) or a polyolefin-based film. The base film may be formed by coating a polyethylene film or a polyolefin film with silicone or TEFLON (tetrafluoroethylene). The adhesive layer may be made of, for example, an acrylic polymer resin, an epoxy resin, or a mixture thereof.

First and second data storage patterns DSP1 and SDP2, first and second storage contacts SC1 and SC2, a first interlayer IL1, a mask pattern HM, a storage capping material layer P240, a first insulating material layer PMD1, and a first substrate 101 may be sequentially disposed on a carrier substrate.

Next, the first substrate 101 located on the first insulating material layer PMD1 may be removed through a grinding process or an etching process, etc.

A gate capping material layer P241 is formed on the first insulating material layer PMD1. The gate capping material layer P241 may be formed by depositing an insulating material on the first insulating material layer PMD1.

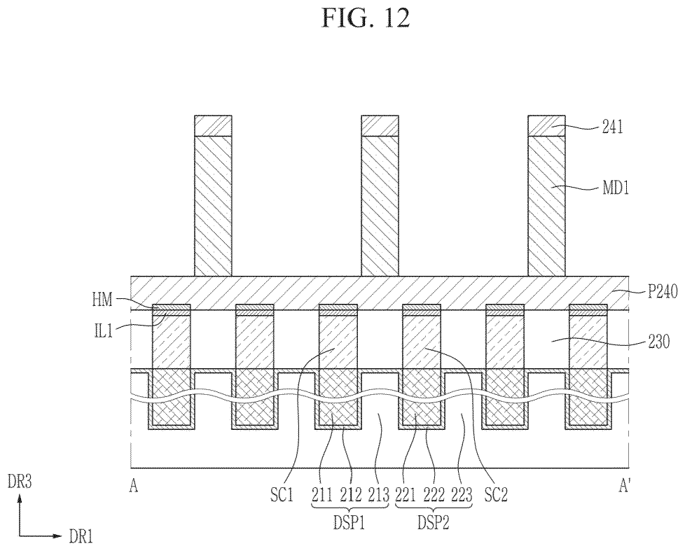

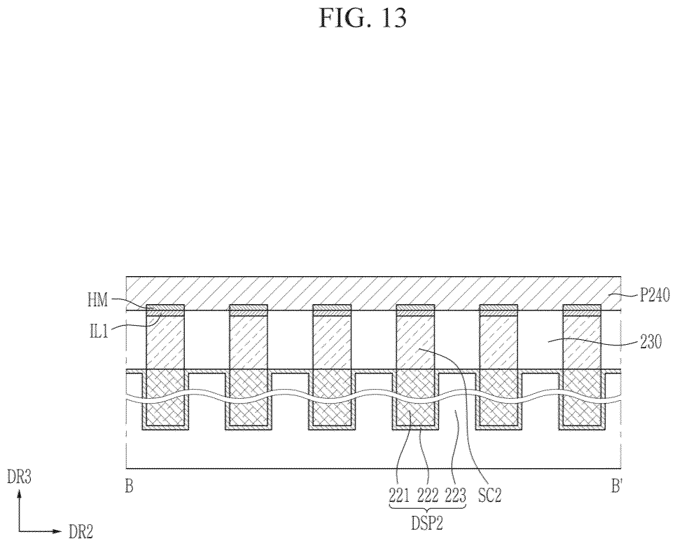

FIG. 12 is a drawing corresponding to a cross-sectional view taken along line A-A′ of FIG. 1. FIG. 13 is a drawing corresponding to a cross-sectional view taken along line B-B′ of FIG. 1.

Referring to FIGS. 12 and 13, a hardmask pattern is formed on the first insulating material layer PMD1 and the gate capping material layer P241, and the first insulating material layer PMD1 and the gate capping material layer P241 are patterned using the hardmask pattern as an etching mask, thereby forming the first insulating pattern MD1 and the gate capping pattern 241. For example, the patterning may utilize dry etching.

However, at this time, since the storage capping material layer P240 and the first insulating material layer PMD1 have different etch rates, the storage capping material layer P240 is not patterned. Through this, the separation distance between the first and second word lines WL1 and WL2, which will be formed subsequently, and the first and second storage contacts SC1 and SC2 may be secured.

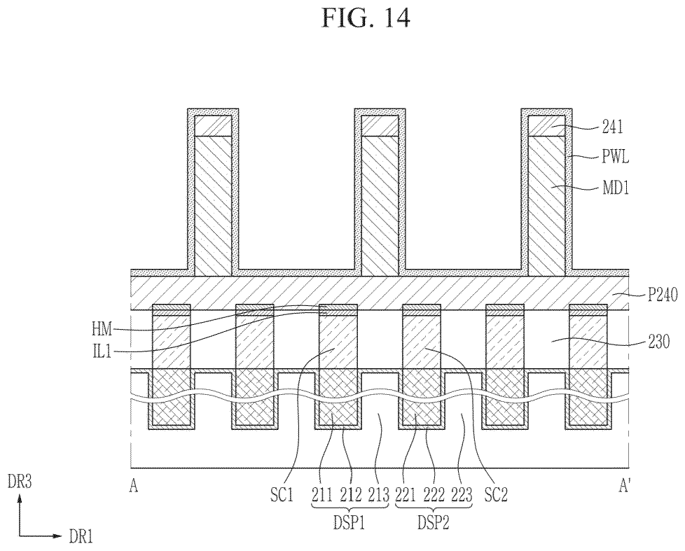

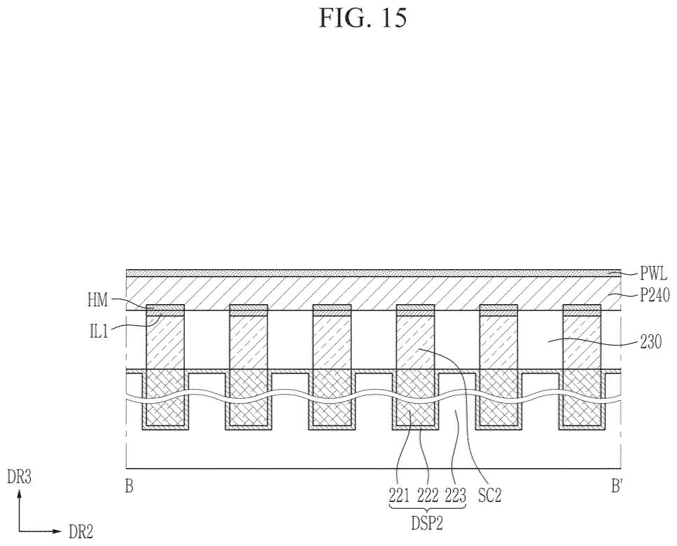

FIG. 14 is a drawing corresponding to a cross-sectional view taken along line A-A′ of FIG. 1. FIG. 15 is a drawing corresponding to a cross-sectional view taken along line B-B′ of FIG. 1.

Referring to FIGS. 14 and 15, a conductive material is deposited on first insulating pattern MD1, gate capping pattern 241, and storage capping material layer P240 to form a word line material layer PWL. The word line material layer PWL may cover the side surface of the first insulating pattern MD1, the upper surface and side surface of the gate capping pattern 241, and the upper surface of the storage capping material layer P240. The word line material layer PWL may be formed conformally. In other words, the thickness of the portion of the word line material layer PWL on the upper surface of the gate capping pattern 241 and the upper surface of the storage capping material layer P240 along the third direction DR3 may be similar to the thickness of the portion of the word line material layer PWL positioned on the side surface of the first insulating pattern MD1 and the side surface of the gate capping pattern 241 along the first direction DR1.

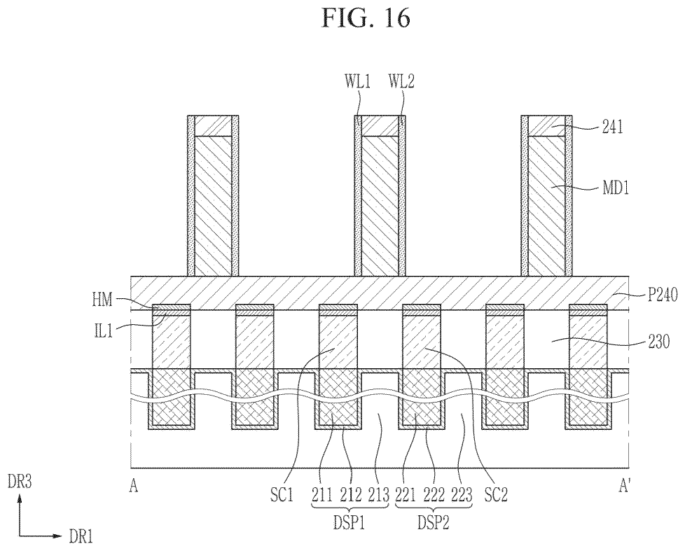

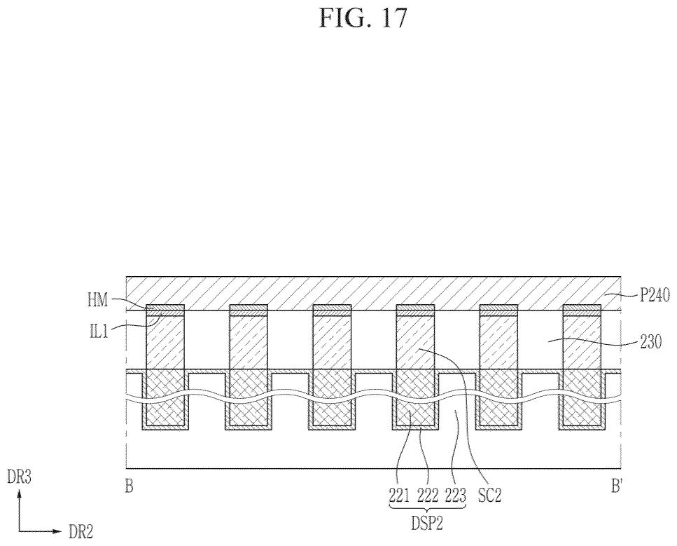

FIG. 16 is a drawing corresponding to a cross-sectional view taken along line A-A′ of FIG. 1. FIG. 17 is a drawing corresponding to a cross-sectional view taken along line B-B′ of FIG. 1.

Referring to FIGS. 16 and 17, a word line material layer PWL is etched to form a first word line WL1 and a second word line WL2 on both sides of a first insulating pattern MD1.

For example, a portion of the word line material layer PWL may be removed via anisotropic etching without using a separate mask. A portion of the word line material layer PWL on the upper surface of the gate capping pattern 241 and the upper surface of the storage capping material layer P240 may be removed, and a portion of the word line material layer PWL on the side surface of the first insulating pattern MD1 and the side surface of the gate capping pattern 241 may remain. The word line material layer PWL remaining on one side of the first insulating pattern MD1, for example, the left side, may become the first word line WL1. The remaining word line material layer PWL on the other side of the first insulating pattern MD1, for example, the right side, may become a second word line WL2.

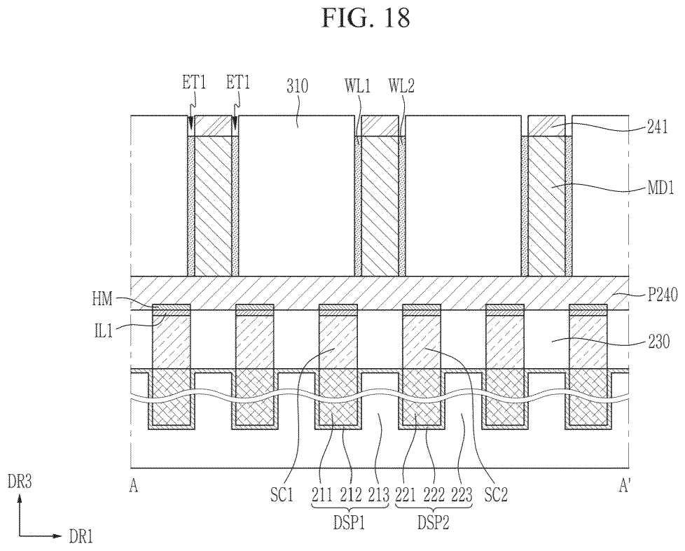

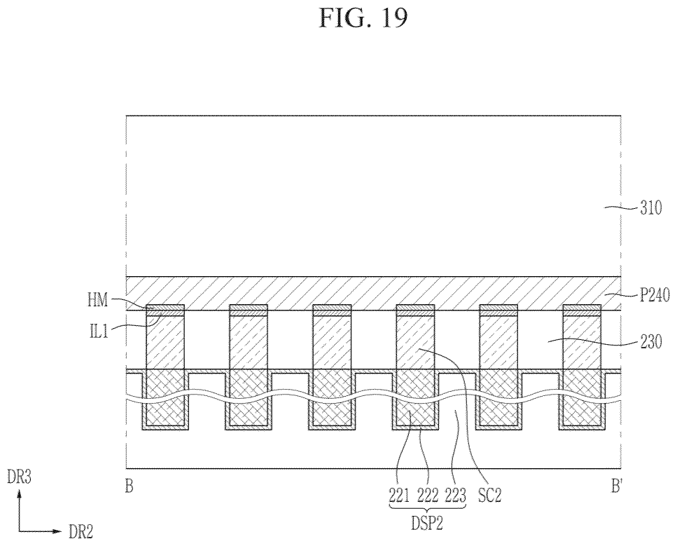

FIG. 18 is a drawing corresponding to a cross-sectional view taken along line A-A′ of FIG. 1. FIG. 19 is a drawing corresponding to a cross-sectional view taken along line B-B′ of FIG. 1.

Referring to FIGS. 18 and 19, a sacrificial layer 310 is filled in the space between the first insulating patterns MD1. The sacrificial layer 310 may be formed using a carbon-based material. When using a carbon-based material, the sacrificial layer 310 may be formed by coating a spin on hard mask or depositing an amorphous carbon layer.

The sacrificial layer 310 may be planarized until the upper surface of the gate capping pattern 241 is exposed. The planarizing of the sacrificial layer 310 may be performed using an etch back or Chemical Mechanical Polishing (CMP) process.

A hard mask pattern may be formed on the sacrificial layer 310 and the gate capping pattern 241, and the first word line WL1 and the second word line WL2 may be etched back using the hard mask pattern as an etching mask to form a first empty space ET1.

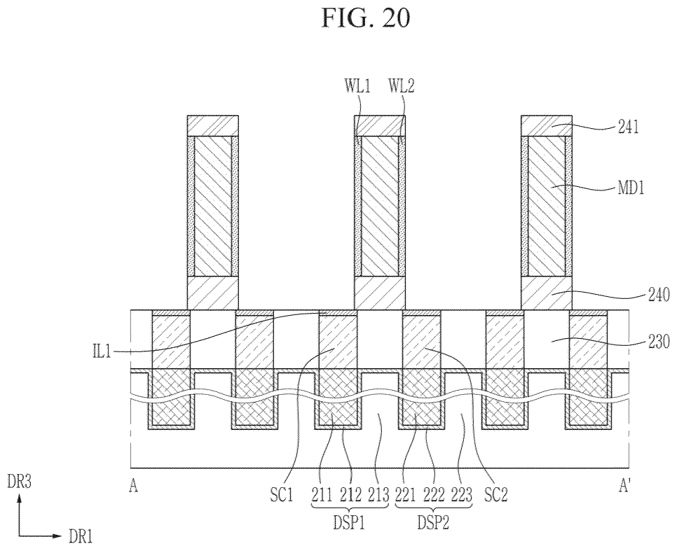

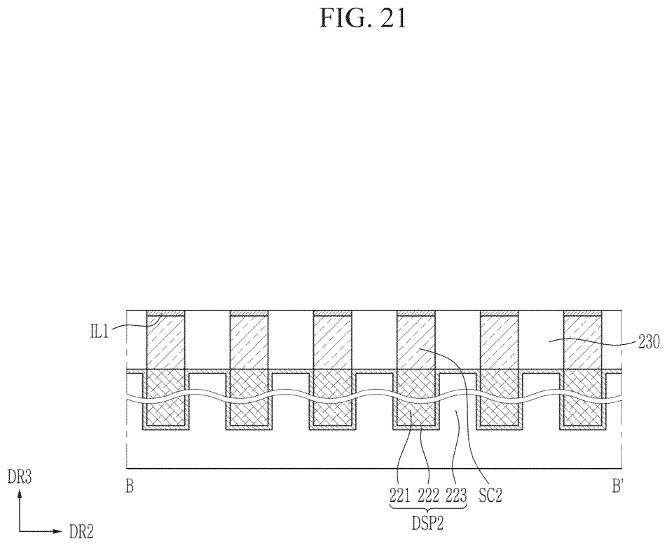

FIG. 20 is a drawing corresponding to a cross-sectional view taken along line A-A′ of FIG. 1. FIG. 21 is a drawing corresponding to a cross-sectional view taken along line B-B′ of FIG. 1.

Referring to FIGS. 20 and 21, after an insulating material is deposited on the gate capping pattern 241 and the sacrificial layer 310 to fill the first empty space ET1, the insulating material may be planarized until the upper surface of the gate capping pattern 241 is exposed. The planarizing of the insulating material may be performed using an etch back or CMP process.

At this time, if the insulating material filling the first empty space ET1 and the insulating material of the gate capping pattern 241 are the same, the interface between the insulating material filling the first empty space ET1 and the gate capping pattern 241 may not be recognized, and the insulating material filling the first empty space ET1 may be conveniently illustrated as the gate capping pattern 241.

Next, the sacrificial layer 310 is removed. For example, when the sacrificial layer 310 is formed of a carbon-based material, the sacrificial layer 310 may be removed through a process such as ashing or stripping.

The storage capping material layer P240 is etched back using the first insulating pattern MD1 as an etching mask to form a storage capping pattern 240. At this time, since the storage capping material layer P240 and the first insulating pattern MD1 have different etch rates, the first insulating pattern MD1 is not patterned. In an embodiment, since the first interlayer IL1 is protected by the mask pattern HM, the first interlayer IL1 is not removed when the storage capping material layer P240 is etched back.

The mask pattern HM is removed. For example, if the mask pattern HM is formed using a material having an etching selectivity with respect to the first interface material layer, it may be removed using wet etching, and if the mask pattern HM is formed using a carbon-based material, it may be removed using a process such as ashing or stripping.

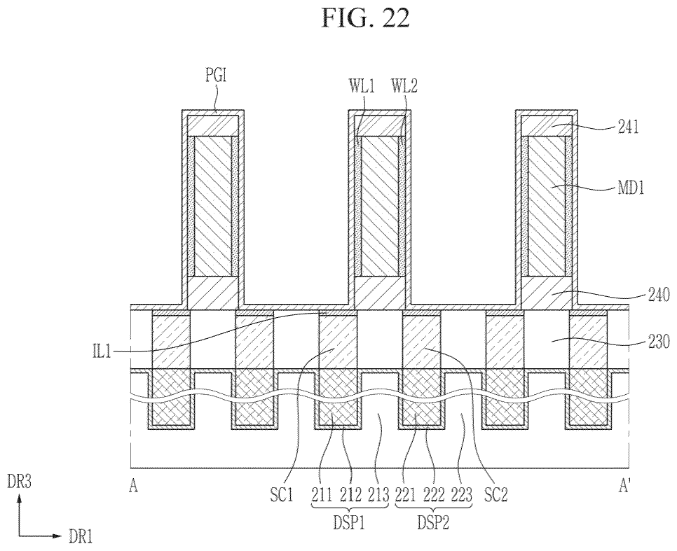

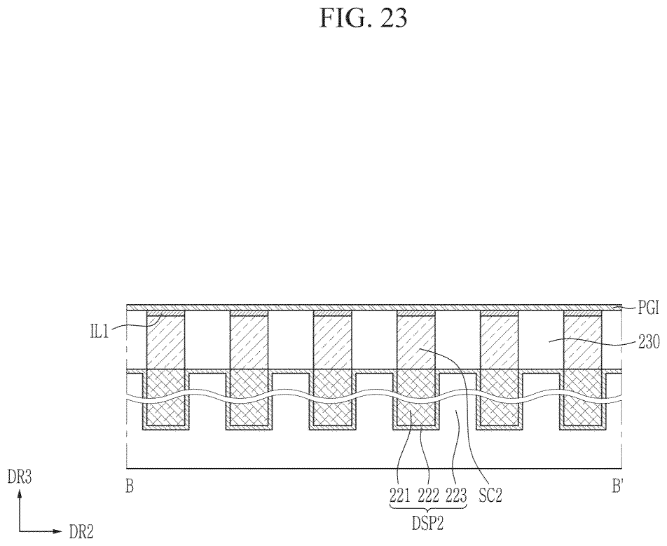

FIG. 22 is a drawing corresponding to a cross-sectional view taken along line A-A′ of FIG. 1. FIG. 23 is a drawing corresponding to a cross-sectional view taken along line B-B′ of FIG. 1.

Referring to FIGS. 22 and 23, a gate insulating material layer PGI may be formed by depositing an insulating material over a first word line WL1 and a second word line WL2. A gate insulating material layer PGI may cover one side of the first word line WL1, one side of the second word line WL2, an upper surface and a side surface of the gate capping pattern 241, a side surface of the storage capping pattern 240, an upper surface of the first interlayer IL1, and an upper surface of the second interlayer insulating layer 230.

The gate insulating material layer PGI may be formed conformally. In other words, the thickness of the gate insulating material layer PGI on the upper surface of the gate capping pattern 241, the upper surface of the first interlayer IL1, and the upper surface of the second interlayer insulating layer 230 along the third direction DR3 may be similar to the thickness of the gate insulating material layer PGI on one side of the first word line WL1, one side of the second word line WL2, the side of the gate capping pattern 241, and the side of the storage capping pattern 240 along the first direction DR1.

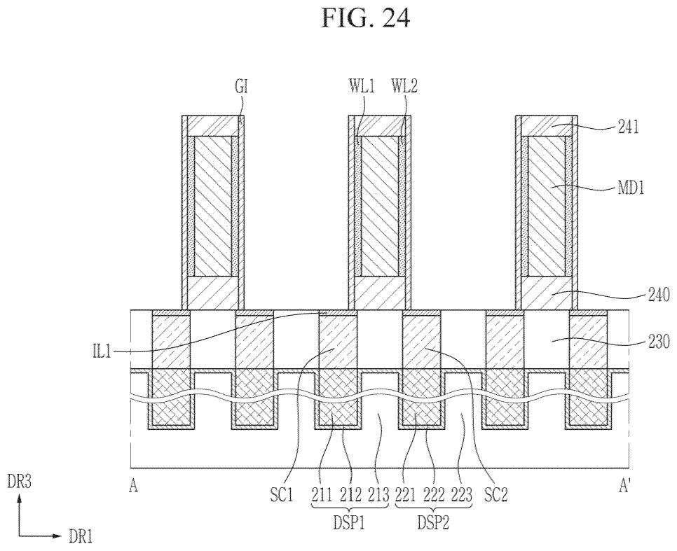

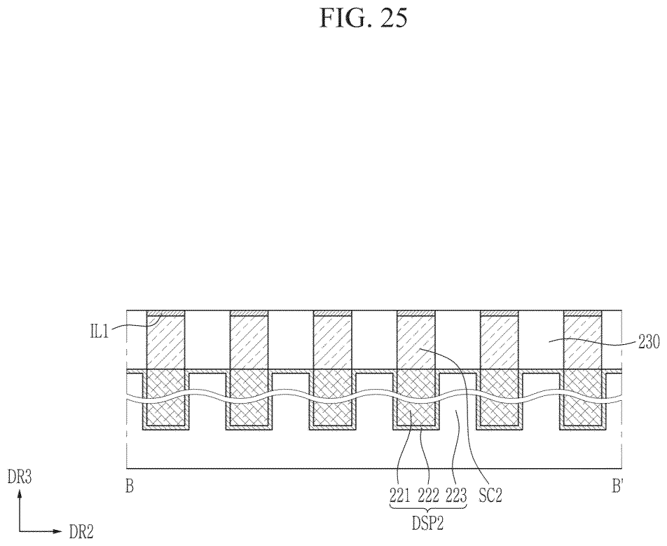

FIG. 24 is a drawing corresponding to a cross-sectional view taken along line A-A′ of FIG. 1. FIG. 25 is a drawing corresponding to a cross-sectional view taken along line B-B′ of FIG. 1.

Referring to FIGS. 24 and 25, a gate insulating material layer PGI may be patterned to form a gate insulating pattern GI on one side of a first word line WL1 and one side of a second word line WL2. For example, a portion of the gate insulating material layer PGI on the upper surface of the gate capping pattern 241, the upper surface of the first interlayer IL1, and the upper surface of the second interlayer insulating layer 230 may be removed, and a portion of the gate insulating material layer PGI positioned on one side of the first word line WL1, one side of the second word line WL2, the side of the gate capping pattern 241, and the side of the storage capping pattern 240 may remain. The gate insulating pattern GI may be located continuously to cover one side of the storage capping pattern 240, one side of the first word line WL1, and one side of the gate capping pattern 241. The gate insulating pattern GI may be located continuously to cover one side of the storage capping pattern 240, one side of the second word line WL2, and one side of the gate capping pattern 241.

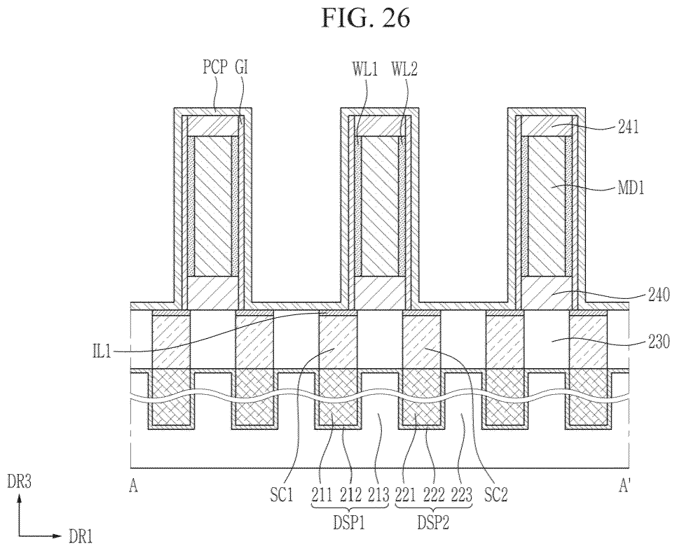

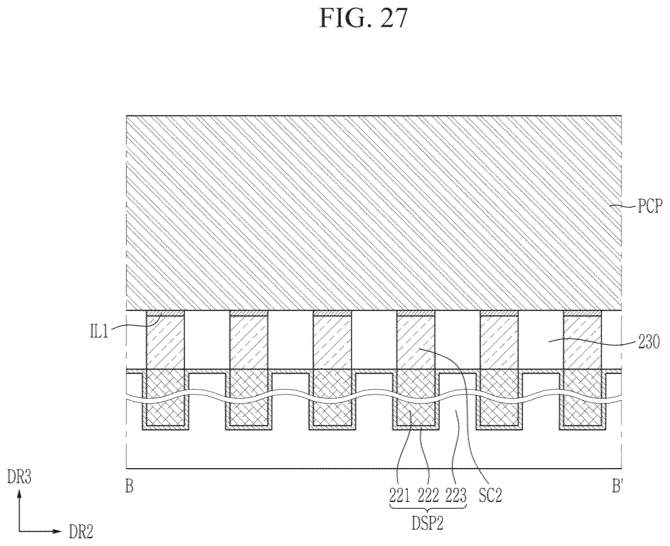

FIG. 26 is a drawing corresponding to a cross-sectional view taken along line A-A′ of FIG. 1. FIG. 27 is a drawing corresponding to a cross-sectional view taken along line B-B′ of FIG. 1.

Referring to FIGS. 26 and 27, a semiconductor material may be deposited on a gate insulating pattern GI to form a channel material layer PCP. The channel material layer PCP may include an oxide semiconductor material. The channel material layer PCP may be formed to surround the gate insulating pattern GI. The channel material layer PCP may cover an upper surface of the gate capping pattern 241. The channel material layer PCP may cover the portions where the first storage contact SC1, the second storage contact SC2, the first interlayer IL1, and the second interlayer insulating layer 230 are exposed. The channel material layer PCP may be formed conformally.

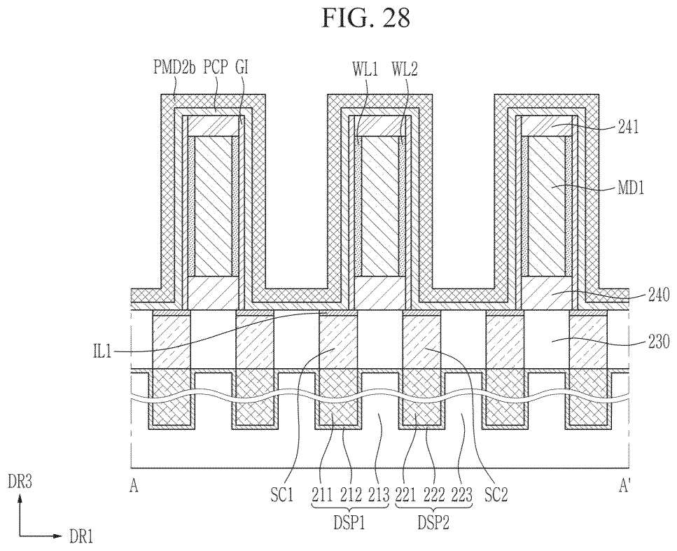

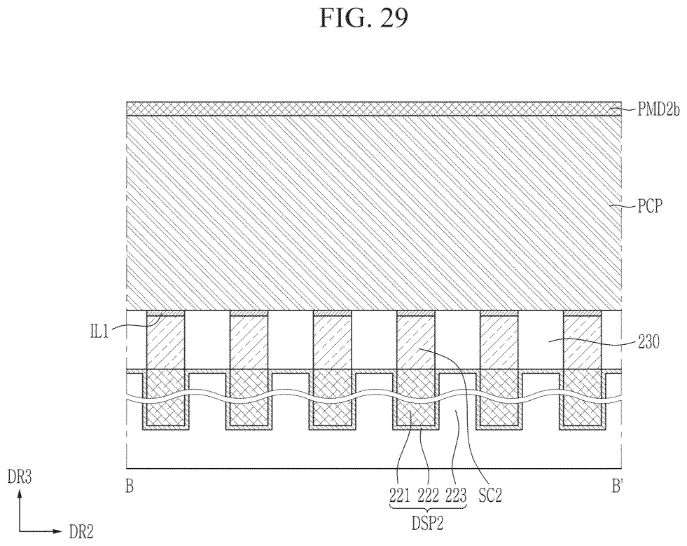

FIG. 28 is a drawing corresponding to a cross-sectional view taken along line A-A′ of FIG. 1. FIG. 29 is a drawing corresponding to a cross-sectional view taken along line B-B′ of FIG. 1.

Referring to FIGS. 28 and 29, an insulating material may be deposited on a channel material layer PCP to form an insulating liner material layer PMD2b. For example, the insulating liner material layer PMD2b may include silicon oxide. An insulating liner material layer PMD2b may be formed to surround the channel material layer PCP. The insulating liner material layer PMD2b may be formed conformally.

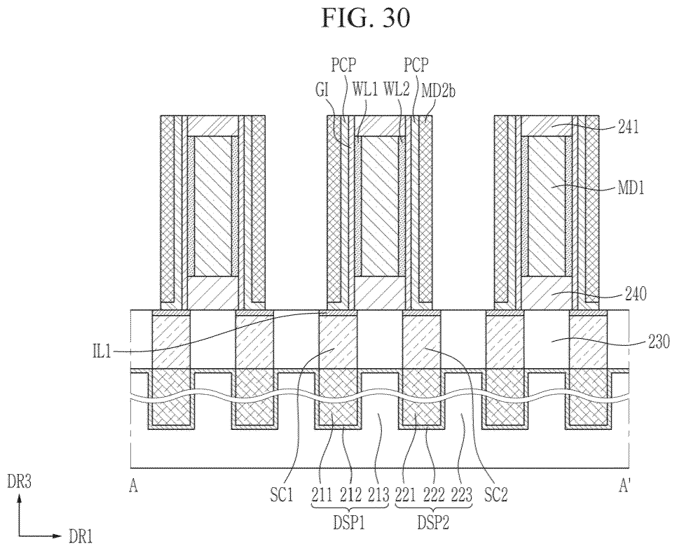

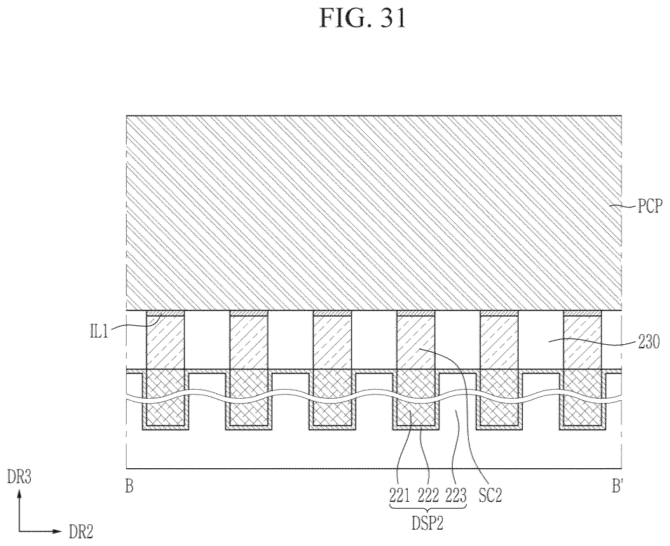

FIG. 30 is a drawing corresponding to a cross-sectional view taken along line A-A′ of FIG. 1. FIG. 31 is a drawing corresponding to a cross-sectional view taken along line B-B′ of FIG. 1.

Referring to FIGS. 30 and 31, the insulating liner material layer PMD2b may be etched to form an insulating liner MD2b. For example, etching of the insulating liner material layer PMD2b may utilize an etch back process.

In an embodiment, a portion of the channel material layer PCP may be removed by etching the channel material layer PCP. For example, etching of the channel material layer PCP can utilize wet etching.

Accordingly, a portion of the insulating liner material layer PMD2b and the channel material layer PCP on the upper surface of the gate capping pattern 241 and the upper surface of the second interlayer insulating layer 230 may be removed, and a portion of the insulating liner material layer PMD2b and the channel material layer PCP on both sides of the gate insulating pattern GI may remain.

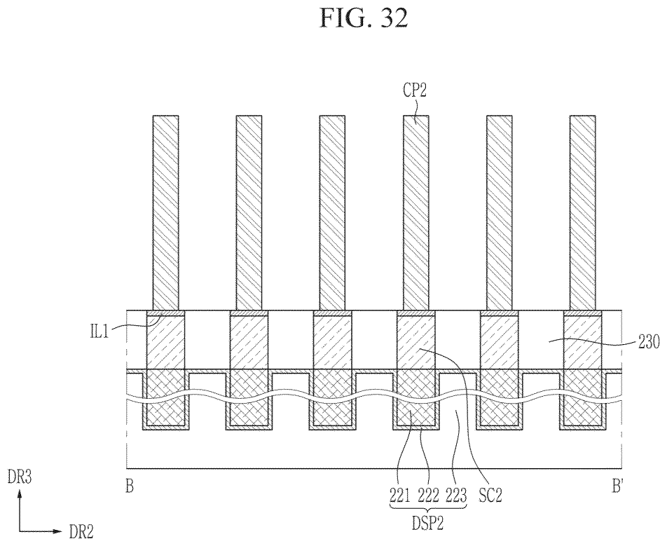

FIG. 32 is a drawing corresponding to a cross-sectional view taken along line B-B′ of FIG. 1. At this time, the drawing corresponding to the cross-sectional view cut along the line A-A′ of FIG. 1 may be the same as FIG. 30, and thus it is omitted.

Referring to FIG. 32, the channel material layer PCP is etched to form first and second channel patterns CP1 and CP2.

For example, the etching process of the channel material layer PCP may be performed using a separate mask. The etching of the channel material layer PCP may be performed using wet etching.

In this way, by forming the first and second channel patterns CP1 and CP2 to have first and second horizontal portions CP1b and CP2b covering the upper surfaces of the first and second storage contacts SC1 and SC2, the contact area between the first and second channel patterns CP1 and CP2 and the first and second storage contacts SC1 and SC2 may be improved.

In an embodiment, by inserting a first interlayer IL1 between the first and second channel patterns CP1 and CP2 and the first and second storage contacts SC1 and SC2, the contact resistance may be reduced and the on-current (Iₒₙ) enhancement may be maximized.

At this time, as described above, by forming the first and second word lines WL1 and WL2 first and then forming the first and second channel patterns CP1 and CP2 later, the first and second horizontal portions CP1b and CP2b of the first and second channel patterns CP1 and CP2 extend in a direction away from the first and second word lines WL1 and WL2, so that the first and second horizontal portions CP1b and CP2b of the first and second channel patterns CP1 and CP2 and the first and second word lines WL1 and WL2 do not overlap in the third direction DR3, thereby securing an effective separation distance from a field perspective between the first and second horizontal portions CP1b and CP2b of the first and second channel patterns CP1 and CP2 and the first and second word lines WL1 and WL2.

In an embodiment, when the first and second word lines WL1 and WL2 are formed first and the first and second channel patterns CP1 and CP2 are formed and CP2 may be formed continuously without etching, thereby preventing damage to the interface between the gate insulating pattern GI and the first and second channel patterns CP1 and CP2 due to etching.

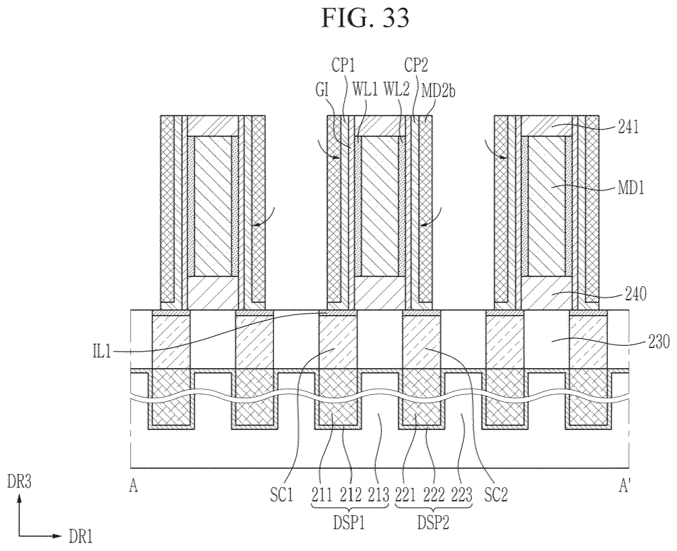

FIG. 33 is a drawing corresponding to a cross-sectional view taken along line A-A′ of FIG. 1. At this time, the drawing corresponding to the cross-sectional view cut along the B-B′ line of FIG. 1 may be identical to FIG. 32, and thus it is omitted.

Referring to FIG. 33, an annealing process may be performed to supply oxygen to the first channel pattern CP1 and the second channel pattern CP2. The first channel pattern CP1 and the second channel pattern CP2 may include an oxide semiconductor material. The insulating liner MD2b covering the first channel pattern CP1 and the second channel pattern CP2 may include silicon oxide. When the annealing process is performed, oxygen may be supplied to the first channel pattern CP1 and the second channel pattern CP2 through the insulating liner MD2b made of silicon oxide. A first channel pattern CP1 and a second channel pattern CP2 having conductor characteristics may have semiconductor characteristics through an annealing process.

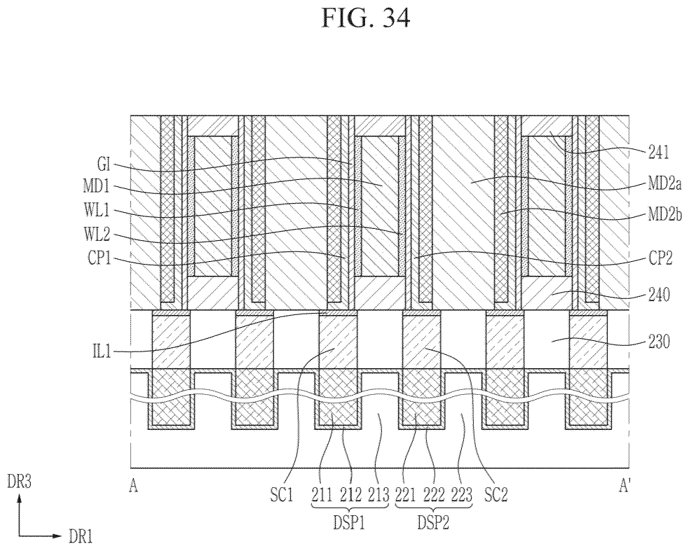

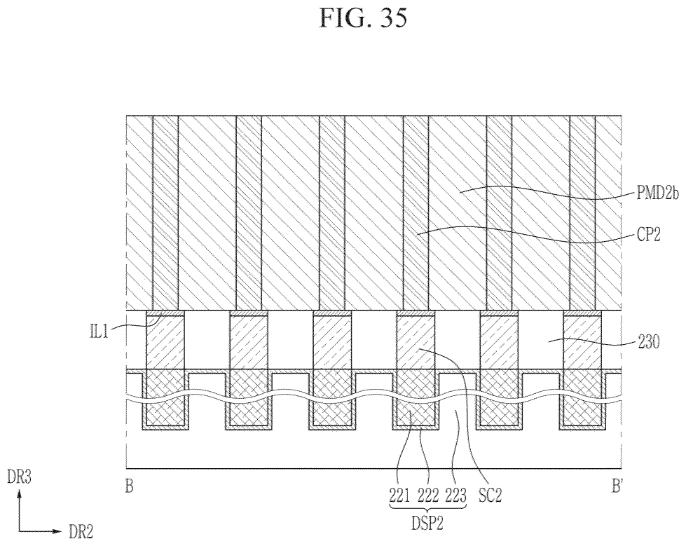

FIG. 34 is a drawing corresponding to a cross-sectional view taken along line A-A′ of FIG. 1. FIG. 35 is a drawing corresponding to a cross-sectional view taken along line B-B′ of FIG. 1.

Referring to FIGS. 34 and 35, an insulating material is deposited in the space between the first insulating patterns MD1, and a planarization process is performed to form a gap-fill insulating layer MD2a. For example, the gap-fill insulating layer MD2a may include silicon oxide. The gap-fill insulating layer MD2a may fill the space between adjacent first insulating patterns MD1.

As a planarization process such as a chemical mechanical polishing process is performed, the upper surface of the gap-fill insulating layer MD2a may be located at substantially the same level as the upper surface of the insulating liner MD2b.

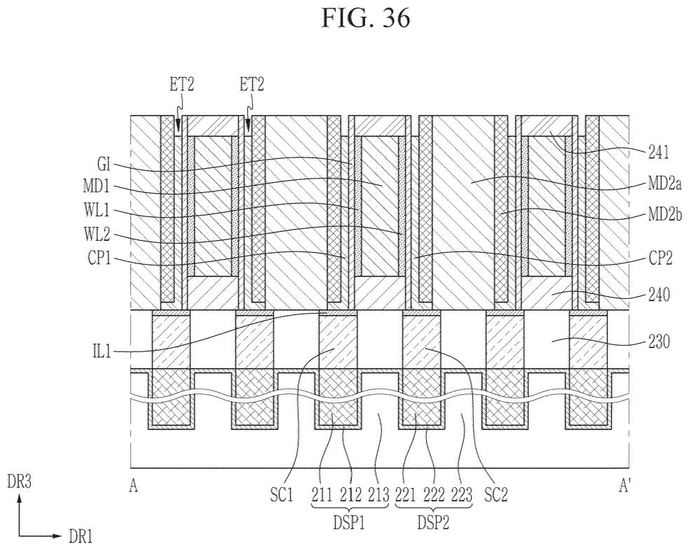

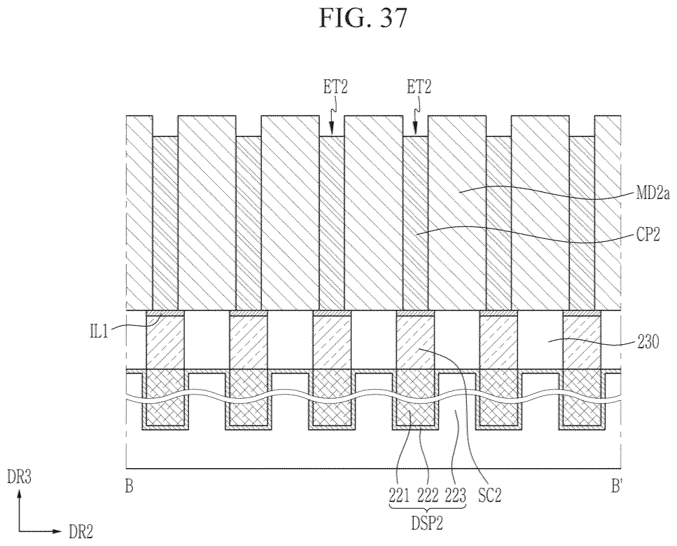

FIG. 36 is a drawing corresponding to a cross-sectional view taken along line A-A′ of FIG. 1. FIG. 37 is a drawing corresponding to a cross-sectional view taken along line B-B′ of FIG. 1.

Referring to FIGS. 36 and 37, a hard mask pattern is formed that covers upper surfaces of the gate capping pattern 241, the gate insulating pattern GI, the gap-fill insulating layer MD2a, and the insulating liner MD2b, and exposes upper surfaces of the first and second channel patterns CP1 and CP2, and the hard mask pattern is used as an etching mask to recess the first and second channel patterns CP1 and CP2 to form a second empty space ET2.

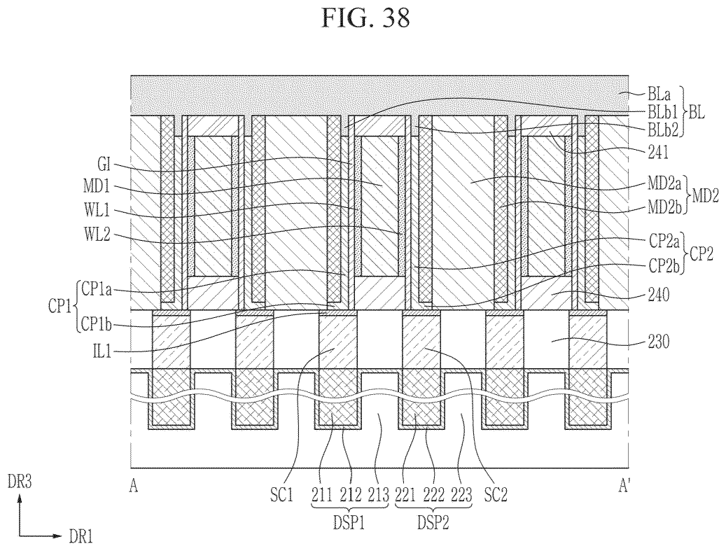

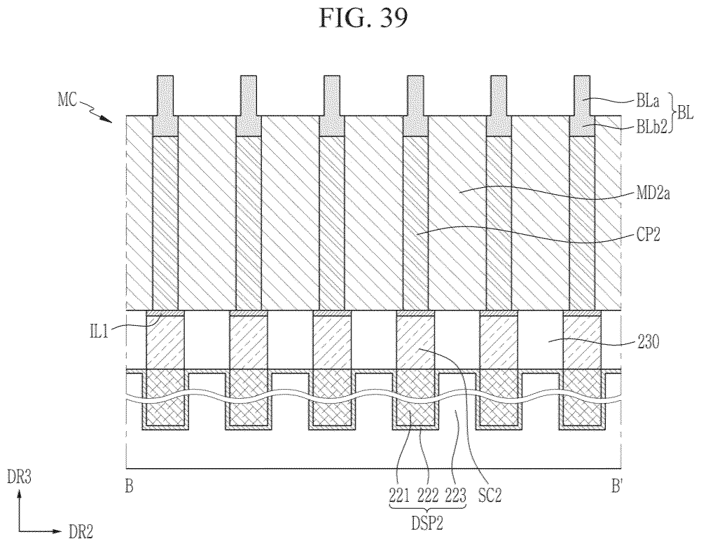

FIG. 38 is a drawing corresponding to a cross-sectional view taken along line A-A′ of FIG. 1. FIG. 39 is a drawing corresponding to a cross-sectional view taken along line B-B′ of FIG. 1.

Referring to FIGS. 38 and 39, a conductive material is deposited on a first channel pattern CP1 and a second channel pattern CP2, and patterned to form a bit line BL.

Referring again to FIGS. 1 to 3, an insulating material may be deposited over a bit line BL to form a bit line capping layer 260. The bit line capping layer 260 may cover the upper surface and side surfaces of the bit line BL. The bit line capping layer 260 may cover the upper surfaces of the gap-fill insulating layer MD2a, the insulating liner MD2b, the first channel pattern CP1, and the second channel pattern CP2 between the bit lines BL.

The bit line capping layer 260 may include a lower layer 262 and an upper layer 264. The lower layer 262 of the bit line capping layer 260 may be first formed on the bit line BL, and then the upper layer 264 of the bit line capping layer 260 may be formed on the lower layer 262. The lower layer 262 and the upper layer 264 of the bit line capping layer 260 may include different materials. For example, the lower layer 262 may include silicon nitride and the upper layer 264 may include silicon oxide.

Next, a conductive material may be deposited on the bit line capping layer 260 to form a shield pattern BLS. The shield pattern BLS may be located entirely over the bit line capping layer 260. The shield pattern BLS may be separated from the bit line BL by a bit line capping layer 260. The shield pattern BLS can overlap the bit line BL in the second direction DR2 and the third direction DR3.

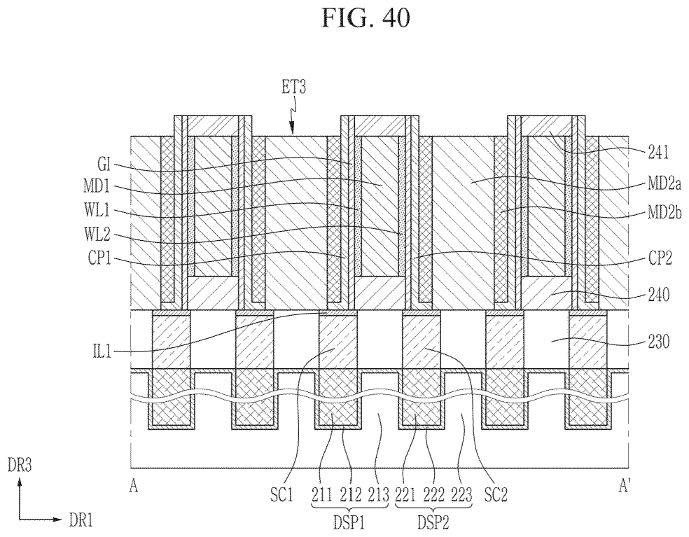

Hereinafter, a method for manufacturing a semiconductor device according to one embodiment will be described with reference to FIGS. 40 to 45. In addition, reference may be made to FIGS. 6, 7, and 8 to 35 described above.

FIGS. 40 to 45 are cross-sectional views showing a method for manufacturing a semiconductor device according to one embodiment of the disclosure in the order of processes.

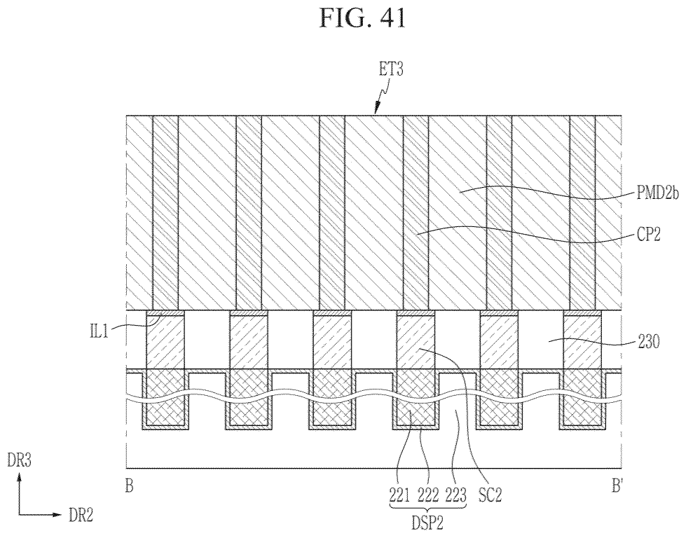

FIG. 40 is a drawing corresponding to a cross-sectional view taken along line A-A′ of FIG. 1. FIG. 41 is a drawing corresponding to a cross-sectional view taken along line B-B′ of FIG. 1.

Referring to FIGS. 40 and 41, a hard mask pattern is formed that covers upper surfaces of the gate capping pattern 241, the gate insulating pattern GI, and the first and second channel patterns CP1 and CP2, and exposes upper surfaces of the gap-fill insulating layer MD2a and the insulating liner MD2b, and the gap-fill insulating layer MD2a and the insulating liner MD2b are etched using the hard mask pattern as an etching mask to form a third empty space ET2. The etching of the gap-fill insulating layer MD2a and the insulating liner MD2b may be performed using wet etching.

The wet etching process may proceed until portions of the side surfaces of the first channel pattern CP1 and the second channel pattern CP2 are exposed. However, the level of the upper surface of the etched gap-fill insulating layer MD2a and insulating liner MD2b may be higher than the level of the upper surface of the first and second word lines WL1 and WL2.

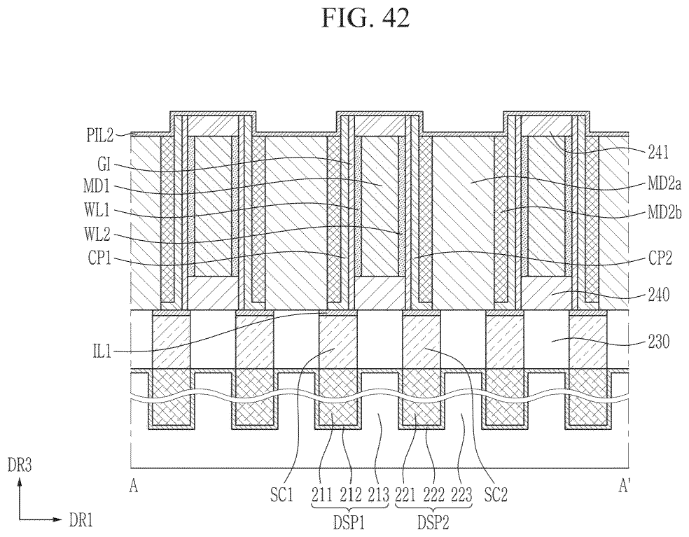

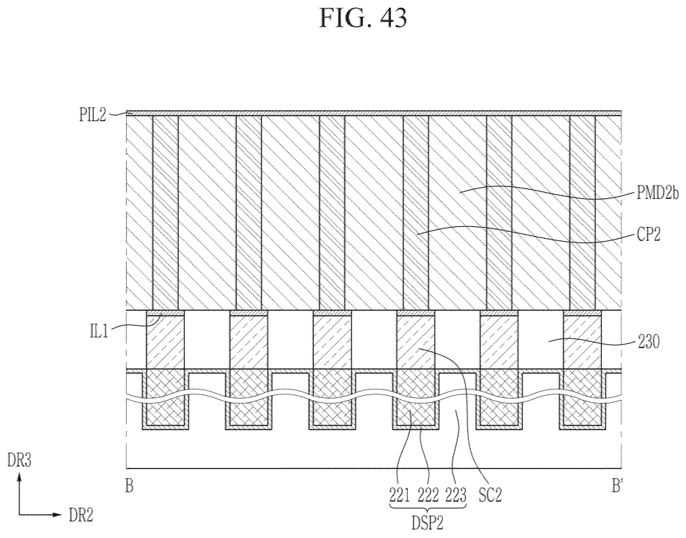

FIG. 42 is a drawing corresponding to a cross-sectional view taken along line A-A′ of FIG. 1. FIG. 43 is a drawing corresponding to a cross-sectional view taken along line B-B′ of FIG. 1.

Referring to FIGS. 42 and 43, a second interface material layer PIL2 is formed on the upper surface of the gate capping pattern 241, the upper surface of the gate insulating pattern GI, the upper surface and some side surfaces of the first and second channel patterns CP1 and CP2, the upper surface of the gap-fill insulating layer MD2a, and the upper surface of the insulating liner MD2b. The second interface material layer PIL2 may be formed conformally.

The second interface material layer PIL2 may be formed by depositing AlOₓ (0<x≤1.5), TiOₓ (0<x≤2), ZnO, C-axis aligned crystalline indium gallium zinc oxide (CAAC-IGZO), or a combination thereof.

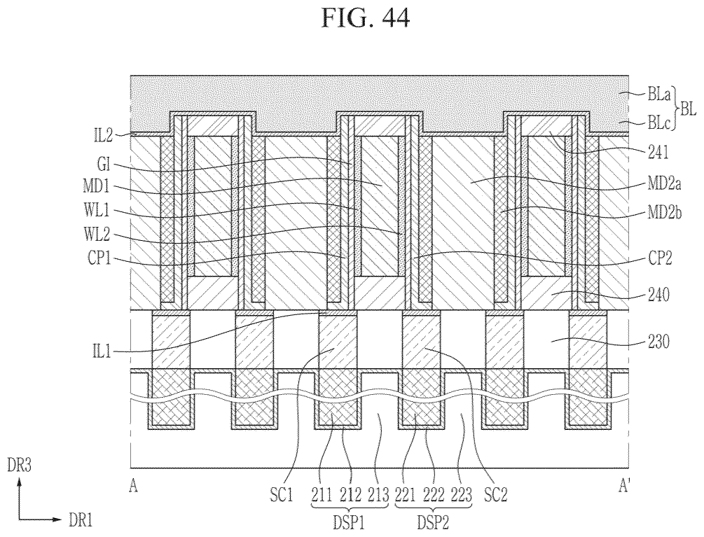

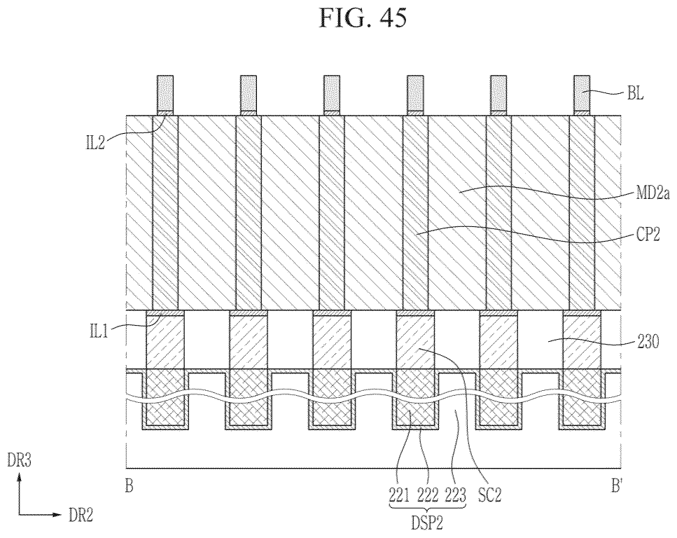

FIG. 44 is a drawing corresponding to a cross-sectional view taken along line A-A′ of FIG. 1. FIG. 45 is a drawing corresponding to a cross-sectional view taken along line B-B′ of FIG. 1.

Referring to FIGS. 44 and 45, a conductive material is deposited on a second interface material layer PIL2 and patterned to form a second interlayer IL2 and a bit line BL.

Referring again to FIGS. 6 and 7, an insulating material may be deposited on the bit line BL to form a bit line capping layer 260, and a conductive material may be deposited over the bit line capping layer 260 to form a shield pattern BLS.

In this way, by forming the bit line BL to have a third protrusion portion BLc protruding toward the first and second channel patterns CP1 and CP2, the contact area between the first and second channel patterns CP1 and CP2 and the bit line BL may be improved.

In an embodiment, by inserting a second interlayer IL2 between the first and second channel patterns CP1 and CP2 and the bit line BL, the contact resistance may be reduced and the on-current (Iₒₙ) enhancement may be maximized.

At this time, as described above, by first forming the first and second word lines WL1 and WL2 and then later forming the first and second channel patterns CP1 and CP2, the bit line BL may be arranged far from the first and second word lines WL1 and WL2 with the third protrusion portion BLc interposed between the first and second channel patterns CP1 and CP2, thereby securing a sufficient separation distance between the bit line BL and the first and second word lines WL1 and WL2.

While this disclosure has been described in connection with what is presently considered to be practical example embodiments, the disclosure is not limited to the disclosed embodiments, but, on the contrary, is intended to cover various modifications and equivalent arrangements included within the spirit and scope of the appended claims.

What is claimed is:

1. A semiconductor device comprising:
a first data storage pattern and a second data storage pattern spaced apart along a first direction;
a first storage contact on the first data storage pattern and a second storage contact on the second data storage pattern;
a first channel pattern on the first storage contact and a second channel pattern on the second storage contact;
a first word line and a second word line extending along a second direction different from the first direction and located between the first channel pattern and the second channel pattern, the first word line provided on the first channel pattern side and the second word line provided on the second channel pattern side;
a bit line located on the first channel pattern and the second channel pattern, the bit line extending along the first direction; and
a first interlayer between the first storage contact and the first channel pattern and between the second storage contact and the second channel pattern.

2. The semiconductor device of claim 1, wherein the first interlayer has a thickness of about 0.5 nm to about 3.0 nm.

3. The semiconductor device of claim 1, wherein the first interlayer comprises AlOₓ (0<x≤1.5), TiOₓ (0<x≤2), ZnO, C-axis aligned crystalline indium gallium zinc oxide (CAAC-IGZO), or a combination thereof.

4. The semiconductor device of claim 1, wherein the semiconductor device further comprises a gate insulating pattern between the first word line and the first channel pattern and between the second word line and the second channel pattern,
wherein a sheet resistance of the first interlayer is smaller than a sheet resistance of the gate insulating pattern, and
wherein the sheet resistance of the first interlayer is larger than a sheet resistance of the first storage contact and a sheet resistance of the second storage contact.

5. The semiconductor device of claim 1, wherein the first channel pattern comprises:
a first vertical portion extending in a third direction perpendicular to the first direction and the second direction, and
a first horizontal portion extending from a lower end of the first vertical portion in the first direction and provided on an upper surface of the first storage contact, and
wherein the second channel pattern comprises:
a second vertical portion extending in a third direction perpendicular to the first direction and the second direction, and
a second horizontal portion extending from a lower end of the second vertical portion in the first direction and provided on an upper surface of the second storage contact.

6. The semiconductor device of claim 5, wherein the first horizontal portion of the first channel pattern extends in the first direction from the lower end of the first vertical portion, and extends in a direction away from the first word line, and
wherein the second horizontal portion of the second channel pattern extends from the lower end of the second vertical portion in the first direction, and extends in a direction away from the second word line.

7. The semiconductor device of claim 4, wherein the bit line comprises:
an extension portion located on the first channel pattern and the second channel pattern and extending in the first direction;
a first protrusion portion protruding in the third direction toward the first channel pattern; and
a second protrusion portion protruding in the third direction toward the second channel pattern.

8. The semiconductor device of claim 7, wherein the semiconductor device further comprises:
a first insulating pattern between the first channel pattern and the second channel pattern; and
a second insulating pattern between a plurality of first insulating patterns spaced apart along the first direction,
wherein an upper surface of the first channel pattern and an upper surface of the second channel pattern are provided at a lower level than an upper surface of the gate insulating pattern and an upper surface of the second insulating pattern,
wherein the first protrusion portion of the bit line is provided between the gate insulating pattern and the second insulating pattern in the first direction and is provided on the upper surface of the first channel pattern, and
wherein the second protrusion portion of the bit line is provided between the gate insulating pattern and the second insulating pattern in the first direction and is provided on the upper surface of the second channel pattern.

9. A semiconductor device comprising:
a first data storage pattern and a second data storage pattern spaced apart from each other along a first direction;
a first storage contact on the first data storage pattern and a second storage contact on the second data storage pattern;
a first channel pattern on the first storage contact and a second channel pattern on the second storage contact;
a first word line and a second word line extending along a second direction different from the first direction and provided between the first channel pattern and the second channel pattern, the first word line provided on the first channel pattern side and the second word line provided on the second channel pattern side;
a bit line provided on the first channel pattern and the second channel pattern and extending along the first direction; and
a second interlayer between the bit line and the first channel pattern and between the bit line and the second channel pattern.

10. The semiconductor device of claim 9, wherein the semiconductor device further comprises:
a gate insulating pattern between the first word line and the first channel pattern and between the second word line and the second channel pattern;
a first insulating pattern between the first channel pattern and the second channel pattern;
a second insulating pattern between a plurality of first insulating patterns spaced apart along the first direction;
a gate capping pattern on the first word line, the second word line, and the first insulating pattern; and
a storage capping pattern on the first storage contact and the second storage contact, and
wherein the second interlayer is provided between the first channel pattern, the second channel pattern, the gate insulating pattern, the gate capping pattern, the second insulating pattern, or a combination thereof, and the bit line.

11. The semiconductor device of claim 10, wherein the bit line comprises:
an extension portion provided on the first channel pattern and the second channel pattern, the extension portion extending in the first direction, and
a third protrusion portion protruding in the third direction toward the second insulating pattern.

12. The semiconductor device of claim 11, wherein the second interlayer is provided between an upper surface of the first channel pattern, an upper surface of the second channel pattern, an upper surface of the gate insulating pattern, an upper surface of the gate capping pattern, or a combination thereof, and the extension portion of the bit line, and
wherein the second interlayer is provided between a side surface of the first channel pattern, a side surface of the second channel pattern, an upper surface of the second insulating pattern, or a combination thereof, and the third protrusion portion of the bit line.

13. A semiconductor device comprising:
a first data storage pattern and a second data storage pattern spaced apart along a first direction;
a first storage contact on the first data storage pattern and a second storage contact on the second data storage pattern;
a first channel pattern on the first storage contact and a second channel pattern on the second storage contact;
a first word line and a second word line extending along a second direction different from the first direction and provided between the first channel pattern and the second channel pattern, the first word line provided on the first channel pattern side and the second word line provided on the second channel pattern side; and
a bit line provided on the first channel pattern and the second channel pattern and extending along the first direction,
wherein the first channel pattern comprises:
a first vertical portion extending in a third direction perpendicular to the first direction and the second direction, and
a first horizontal portion extending from a lower end of the first vertical portion in the first direction and covering an upper surface of the first storage contact,
wherein the second channel pattern comprises:
a second vertical portion extending in a third direction perpendicular to the first direction and the second direction, and
a second horizontal portion extending from a lower end of the second vertical portion in the first direction and provided on an upper surface of the second storage contact,
wherein the first horizontal portion of the first channel pattern extends in the first direction from the lower end of the first vertical portion, and extends in a direction away from the first word line, and
wherein the second horizontal portion of the second channel pattern extends from the lower end of the second vertical portion in the first direction, and extends in a direction away from the second word line.

14. The semiconductor device of claim 13, wherein the first horizontal portion of the first channel pattern and the second horizontal portion of the second channel pattern extend in opposite directions in the first direction,
wherein the first horizontal portion of the first channel pattern does not overlap the first word line in the third direction, and
wherein the second horizontal portion of the second channel pattern does not overlap the second word line in the third direction.

15. The semiconductor device of claim 14, wherein the first horizontal portion of the first channel pattern overlaps the first storage contact in the third direction, and
wherein the second horizontal portion of the second channel pattern overlaps the second storage contact in the third direction.

16. The semiconductor device of claim 14, wherein the first vertical portion of the first channel pattern is provided closer to the first word line than to a first direction middle point of the first storage contact, and
wherein the second vertical portion of the second channel pattern is provided closer to the second word line than to the first direction middle point of the second storage contact.

17. The semiconductor device of claim 13, wherein the semiconductor device further comprises:
a first insulating pattern between the first channel pattern and the second channel pattern; and
a second insulating pattern between a plurality of first insulating patterns spaced apart along the first direction,
wherein the second insulating pattern comprises a gap-fill insulating layer and an insulating liner on both sides of the first direction of the gap-fill insulating layer,
wherein the insulating liner of the second insulating pattern is provided between the first channel pattern and the gap-fill insulating layer and between the second channel pattern and the gap-fill insulating layer, and
wherein a width of the first insulating pattern in the first direction is smaller than a width of the second insulating pattern in the first direction.

18. The semiconductor device of claim 17, wherein the insulating liner of the second insulating pattern is provided on the first horizontal portion of the first channel pattern, and
wherein the insulating liner of the second insulating pattern is provided on the second horizontal portion of the second channel pattern.

19. The semiconductor device of claim 13, wherein the semiconductor device further comprises a first interlayer between the first storage contact and the first channel pattern and between the second storage contact and the second channel pattern.

20. The semiconductor device of claim 13, wherein the semiconductor device further comprises a second interlayer between the bit line and the first channel pattern and between the bit line and the second channel pattern.
